(19) United States
(12) Patent Application Publication
(10) Pub. No.: US 2026/0271561 A1
(43) Pub. Date: Sep. 10, 2026

(54) ELECTRONIC DEVICE AND METHODS OF MANUFACTURING THE SAME

(71) Applicant: Samsung Display Co., Ltd., Yongin-si (KR)

(72) Inventors: Eunji LIM, Yongin-si (KR); IN-BAE KIM, Yongin-si (KR); BEOMSOO PARK, Yongin-si (KR); JAEIK LIM, Yongin-si (KR); JUNG-HYUN CHO, Yongin-si (KR)

(21) Appl. No.: 19/379,202

(22) Filed: Nov. 4, 2025

(30) Foreign Application Priority Data
Mar. 5, 2025 (KR) 10-2025-0028420

(51) Int. Cl. H10K 59/131; H10K 59/12; H10K 59/40; H10K 59/80; H10K 102/00

(52) U.S. Cl. CPC H10K 59/131; H10K 59/1201; H10K 59/40; H10K 59/8791; H10K 2102/311

(57) ABSTRACT

An electronic device includes a display panel including a first non-bending portion, a bending portion, and a second non-bending portion arranged in a first direction, and a plurality of pads in the second non-bending portion, wherein the plurality of pads include a plurality of conductive patterns stacked in a thickness direction of the display panel and a plurality of dummy insulating patterns arranged to be adjacent to both sides of at least one conductive pattern among the plurality of conductive patterns, wherein the at least one conductive pattern among the plurality of conductive patterns includes a first conductive layer, a second conductive layer, and a third conductive layer sequentially stacked from bottom to top in the thickness direction, and the plurality of dummy insulating patterns are arranged between the first conductive layer and the third conductive layer and cover both sides of the second conductive layer.

### CROSS-REFERENCE TO RELATED APPLICATION

The present application claims priority to and the benefit of Korean Patent Application No. 10-2025-0028420, filed on Mar. 05, 2025, in the Korean Intellectual Property Office, the entire content of which is incorporated herein by reference.

### BACKGROUND

### 1. Field

One or more embodiments of the present disclosure relate to an electronic device and a method for manufacturing the electronic device.

### 2. Description of Related Art

Electronic products such as smartphones, digital cameras, notebook computers, navigation systems, and/or smart televisions, which provide visual content (e.g., images) to users, may include electronic devices for displaying images. These electronic devices generate images and present (provide) them to users through a display screen.

With the recent advancements in electronic device technology, various types (kinds) of display devices (display screens) for electronic devices have been developed. For example, electronic devices capable of being curved, folded, and/or rolled have emerged. Such devices are more portable and may enhance user convenience.

### SUMMARY

One or more aspects of embodiments of the present disclosure are directed towards an electronic device and a method for manufacturing the electronic device, in which occurrence of cracks in an input sensing unit when being folded is prevented.

One or more aspects of embodiments of the present disclosure are directed toward an electronic device and a method for manufacturing the electronic device, in which corrosion of a pad may be prevented or reduced.

Additional aspects will be set forth in part in the description which follows and, in part, will be apparent from the description, or may be learned by practice of the presented embodiments.

According to one or more embodiments of the present disclosure, an electronic device includes: a display panel, which is divided into a first non-bending portion, a bending portion, and a second non-bending portion arranged (sequentially arranged) in a first direction and includes a plurality of pads arranged in the second non-bending portion; an input sensing unit on (e.g., arranged on) the display panel; and an anti-reflection layer on (e.g., arranged on) the input sensing unit, wherein the plurality of pads include a plurality of conductive patterns stacked in a thickness direction of the display panel and a plurality of dummy insulating patterns arranged to be adjacent to both sides (e.g., two opposite sides) of at least one conductive pattern among the plurality of conductive patterns, wherein the at least one conductive pattern among the plurality of conductive patterns may include a first conductive layer, a second conductive layer, and a third conductive layer stacked from bottom to top (e.g., sequentially stacked in the thickness direction), and the dummy insulating patterns may be arranged between the first conductive layer and the third conductive layer and cover both sides (e.g., two opposite sides) of the second conductive layer.

In one or more embodiments, the dummy insulating patterns may include an inorganic material.

In one or more embodiments, both ends of the second conductive layer may be arranged further inward than both ends of the first conductive layer and both ends of the third conductive layer. Here, for example, “further inward” refers to a position closer to the center of the pad structure along the first direction, such that the lateral edges of the second conductive layer are located within the outer boundaries defined by the first and third conductive layers.

In one or more embodiments, the input sensing unit may include a base layer in contact with the display panel, a first sensing conductive layer on (e.g., arranged on) the base layer, a first sensing insulating layer on (e.g., arranged on) the first sensing conductive layer, a second sensing conductive layer on (e.g., arranged on) the first sensing insulating layer, and a second sensing insulating layer on (e.g., arranged on) the second sensing conductive layer and including an organic material, wherein the second sensing conductive layer may include a same material as any one of the conductive patterns.

In one or more embodiments, the second sensing insulating layer may not overlap the bending portion and the pads.

In one or more embodiments, the display panel may further include a data driver between (e.g., arranged between) the pads and the bending portion when viewed on a plane (e.g., in plan view), and the second sensing insulating layer may not overlap the data driver.

In one or more embodiments, a thickness of the second sensing insulating layer may be about 3.4 to 3.8 times greater than a thickness of the second sensing conductive layer. For example, the thickness of the second sensing insulating layer may be about 3.4 to 3.8 times the thickness of the second sensing conductive layer.

In one or more embodiments, the first non-bending portion may include a first non-folding region, a folding region, and a second non-folding region arranged (e.g., sequentially arranged) in the first direction, and the second sensing insulating layer may overlap the folding region.

In one or more embodiments, the second conductive layer may include a material different from those of the first conductive layer and the third conductive layer.

According to one or more embodiments of the present disclosure, an electronic device includes a display panel, which is divided into a first non-bending portion, a bending portion, and a second non-bending portion arranged in a first direction and includes a plurality of pads in (e.g., arranged in) the second non-bending portion, and an input sensing unit on (e.g., arranged on) the display panel, wherein the input sensing unit may include a base layer in contact with the display panel, a first sensing conductive layer on (e.g., arranged on) the base layer, a first sensing insulating layer on (e.g., arranged on) the first sensing conductive layer, a second sensing conductive layer on (e.g., arranged on) the first sensing insulating layer, and a second sensing insulating layer on (e.g., arranged on) the second sensing conductive layer and including an organic material, wherein the second sensing insulating layer may not overlap the bending portion and the pads.

In one or more embodiments, the display panel may further include a data driver between (e.g., arranged between) the pads and the bending portion when viewed on a plane (e.g., in plan view), and the second sensing insulating layer may not overlap the data driver.

In one or more embodiments, a thickness of the second sensing insulating layer may be about 3.4 to 3.8 times greater than a thickness of the second sensing conductive layer.

In one or more embodiments, the first non-bending portion may include a first non-folding region, a second non-folding region, and a folding region, which are arranged in the first direction, with the folding region being arranged between the first non-folding region and the second non-folding region and folded around a folding axis parallel to a second direction crossing the first direction, and the second sensing insulating layer may overlap the folding region.

In one or more embodiments, the plurality of pads may include a plurality of conductive patterns stacked in a thickness direction of the display panel and a plurality of dummy insulating patterns arranged adjacent to both sides (e.g., two opposite sides) of at least one conductive pattern among the plurality of conductive patterns.

In one or more embodiments, the at least one conductive pattern among the plurality of conductive patterns may include a first conductive layer, a second conductive layer, and a third conductive layer, which are stacked in a bottom-to-top order, and the dummy insulating patterns may be arranged between the first conductive layer and the third conductive layer and cover both sides (e.g., two opposite sides) of the second conductive layer.

In one or more embodiments, the dummy insulating patterns may include an inorganic material.

In one or more embodiments, both ends of the second conductive layer may be arranged further inward than both ends of the first conductive layer and both ends of the third conductive layer.

In one or more embodiments, the second conductive layer may include a material different from those of the first conductive layer and the third conductive layer.

In one or more embodiments, the electronic device may not include (e.g., may exclude) a polarizing film that may be arranged inside the display panel, between the display panel and the input sensing unit, between the input sensing unit and the anti-reflection layer, or above (e.g., on) the anti-reflection layer. For example, the electronic device may not include (e.g., may exclude) any polarizing film inside the display panel, between the display panel and the input sensing unit, between the input sensing unit and the anti-reflection layer, or on the anti-reflection layer.

According to one or more embodiments of the present disclosure, a method for manufacturing an electronic device includes: preparing a display panel, which is divided into a first non-bending portion, a bending portion, and a second non-bending portion arranged in a first direction and includes a plurality of pads in (e.g., arranged in) the second non-bending portion, and a first sensing conductive layer, a first sensing insulating layer, and a second sensing conductive layer, which are sequentially stacked in the first non-bending portion; providing an organic material on the second non-bending portion and the second sensing conductive layer to form a preliminary sensing insulating layer; etching the preliminary sensing insulating layer overlapping the pads and the bending portion to form a second sensing insulating layer; providing an inorganic material on the second sensing insulating layer, the pads, and the bending portion to form a preliminary insulating layer; and etching the preliminary insulating layer on the first non-bending portion, the bending portion, and the second non-bending portion to form dummy insulating patterns adjacent to both sides (e.g., two opposite sides) of the pads, wherein the plurality of pads include a plurality of conductive patterns stacked in a thickness direction of the display panel, wherein at least one conductive pattern among the plurality of conductive patterns may include a first conductive layer, a second conductive layer, and a third conductive layer stacked in a bottom-to-top order, and the dummy insulating patterns may be arranged between the first conductive layer and the third conductive layer and cover both sides (e.g., two opposite sides) of the second conductive layer.

For example, by eliminating the need for a polarizing film and incorporating a multilayered conductive pad structure with adjacent dummy insulating patterns, one or more embodiments of the present disclosure may enhance mechanical flexibility and environmental durability. These designs contribute to improved reliability of the input sensing unit during repeated folding operations and reduce the risk of corrosion in critical conductive regions.

### BRIEF DESCRIPTION OF DRAWINGS

The accompanying drawings are included to provide a further understanding of the present disclosure, and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a block diagram of an electronic device according to one or more embodiments of the present disclosure;

FIG. 2 illustrates schematic diagrams of electronic devices according to various embodiments of the present disclosure;

FIG. 3 is a perspective view of an electronic device according to one or more embodiments of the present disclosure;

FIG. 4 illustrates a folded state of the electronic device illustrated in FIG. 3 according to one or more embodiments of the present disclosure;

FIG. 5 is an exploded perspective view of the electronic device illustrated in FIG. 3 according to one or more embodiments of the present disclosure;

FIG. 6 is a cross-sectional view of a display module DM according to one or more embodiments of the present disclosure;

FIG. 7 is a plan view of a display panel according to one or more embodiments of the present disclosure;

FIG. 8 is a plan view of an input sensing unit according to one or more embodiments of the present disclosure;

FIG. 9A is a cross-sectional view of a display device corresponding to the line I-I' illustrated in FIG. 5 according to one or more embodiments of the present disclosure;

FIG. 9B illustrates a state in which a bending region illustrated in FIG. 9A is bent according to one or more embodiments of the present disclosure;

FIG. 10A is a cross-sectional view of a window module and a display module illustrated in FIG. 9A according to one or more embodiments of the present disclosure;

FIG. 10B is a cross-sectional view for explaining a folded state of the window module and the display module according to one or more embodiments of the present disclosure;

FIG. 11 is a perspective view illustrating a portion of the display panel illustrated in FIG. 7 according to one or more embodiments of the present disclosure;

FIG. 12A is a cross-sectional view of an electronic panel corresponding to the line II‒II' illustrated in FIG. 7 according to one or more embodiments of the present disclosure;

FIG. 12B is a cross-sectional view of the electronic panel corresponding to the line II‒II' illustrated in FIG. 7 according to one or more embodiments of the present disclosure;

FIG. 12C is a cross-sectional view of the electronic panel corresponding to the line II‒II' illustrated in FIG. 7 according to one or more embodiments of the present disclosure.

FIG. 13 is a cross-sectional view illustrating a portion of the electronic panel according to one or more embodiments of the present disclosure;

FIG. 14 is an enlarged cross-sectional view of a first signal pad PD1 illustrated in FIG. 12A according to one or more embodiments of the present disclosure; and

FIGS. 15A ‒ 15E are cross-sectional views for explaining a method for manufacturing a second sensing insulating layer illustrated in FIG. 12A and a method for manufacturing a dummy insulating pattern illustrated in FIG. 14 according to one or more embodiments of the present disclosure.

### DETAILED DESCRIPTION

Embodiments of the present disclosure may be modified and practiced in many alternate forms, and thus example embodiments will be exemplified in the drawings and described in more detail. It should be understood, however, that it is not intended to limit the disclosure to the particular forms disclosed, but rather, is intended to cover all modifications, equivalents, and alternatives falling within the spirit and scope of the disclosure.

In this disclosure, it will be understood that if (e.g., when) an element (or region, layer, portion, and/or the like) is referred to as being "on", "connected to" or

"coupled to" another element, it can be directly on, connected or coupled to the other element, or one or more intervening elements may be present therebetween. In contrast, “directly on” may refer to that there are no additional intervening elements or layers between the element or layer and the other element or layer. In addition, if (e.g., when) a layer, a film, a region, a plate, and/or the like is referred to as being "under" or "below" another part, it may be "directly under" the other part, or one or more intervening layers may be present therebetween. Also, if (e.g., when) an element is referred to as being arranged "on" another element, it may be arranged under the other element.

Like reference numerals refer to like elements throughout the disclosure, and duplicative descriptions thereof may not be provided for conciseness. In addition, in the drawings, the thicknesses, ratios, and dimensions of elements may be exaggerated or reduced for effective description of the technical contents. As used herein, the term "and/or" or “or” may include any and all combinations that the associated configurations can define.

Although the terms “first,” “second,” and/or the like may be used herein to describe one or more suitable components, these components should not be limited by these terms. These terms are used only to distinguish one component, part, region, layer, or portion from another component, part, region, layer, or portion. For example, without departing from the scope and teachings of the present disclosure, a first component, a first part, a first region, a first layer, or a first portion may be referred to as a second component, a second part, a second region, a second layer, or a second portion, and similarly, a second component, a second part, a second region, a second layer, or a second portion may also be referred to as a first component, a first part, a first region, a first layer, or a first portion. Singular expressions include plural expressions unless the context clearly indicates otherwise. For example, the singular forms, “a,” “an,” and “the” are intended to include the plural forms as well, unless the context clearly indicates otherwise. Further, the use of “may” when describing embodiments of the present disclosure refers to “one or more embodiments of the present disclosure."

In addition, terms, such as "below", "lower", "above", "upper" and/or the like, are used herein for ease of description to describe one element's relation to another element(s) as illustrated in the drawings. The above terms are relative concepts and are described based on the directions indicated in the drawings.

It will be understood that the terms “comprise(s)/comprising” and/or "include(s)/including" and/or "has(have)/having", if (e.g., when) used in this disclosure, specify the presence of stated features, numbers, steps, operations, elements, components, and/or groups thereof, but do not preclude the presence or addition of one or more other features, numbers, steps, operations, elements, components, and/or groups thereof. Additionally, the terms “comprise(s)/comprising,” “include(s)/including,” “has(have)/having”, or other similar terms include or support the terms “consisting of” and “consisting essentially of,” indicating the presence of stated features, numbers, steps, operations, parts, and/or components, without or essentially without the presence of other features, numbers, steps, operations, parts, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to the accompanying drawings.

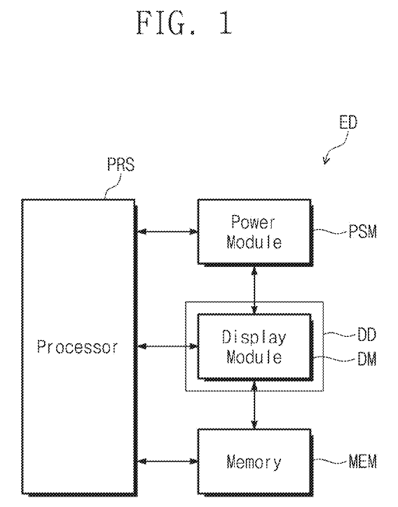

FIG. 1 is a block diagram of an electronic device according to one or more embodiments of the present disclosure.

Referring to FIG. 1, an electronic device ED according to one or more embodiments of the disclosure may include a display device DD that provides an image to a user and may further include a module or a device having an additional function in addition to the display device DD. The electronic device ED according to one or more embodiments of the disclosure may include a display module DM, a processor PRS, a memory MEM, and a power module PSM, and the display device DD may include the display module DM.

The processor PRS may include at least one of a central processing unit (CPU), an application processor (AP), a graphic processing unit (GPU), a communication processor (CP), an image signal processor ISP, or a controller. The processor PRS may process an image signal and provide the image signal to the display device DD, and the display device DD may generate an image corresponding to the image signal.

In one or more embodiments of the disclosure, the processor PRS may be provided by being divided into two or more portions from a functional or structural perspective. For example, in one or more embodiments, the processor PRS may include a main processor in the form of a first driving chip including a central processing unit and an auxiliary processor in the form of a second driving chip including a controller configured to receive an image signal from the main processor and process the image signal to meet an interface specification of the display module DM.

The memory MEM may store data information necessary for an operation of the processor PRS or the display module DM. When the processor PRS executes an application stored in the memory MEM, an image data signal and/or an input control signal is transmitted to the display module DM, and the display module DM may process the received signal and output image information through a display screen.

The power module PSM may include a power supply module, such as a power adapter or a battery device, and a power conversion module configured to convert power supplied by the power supply module to generate power necessary for an operation of the electronic device ED. The power module PSM may supply power to the display module DM and the processor PRS.

At least one of (e.g., at least one selected from among) the components of the electronic device ED described above may be included in the display device DD according to the embodiments of the disclosure described above. In one or more embodiments, some of the individual modules functionally included in one module may be included in the display device DD, and the others thereof may be provided separately from the display device DD. For example, in one or more embodiments, the display device DD may include the display module DM, and the processor PRS, the memory MEM, and the power module PSM may be provided in the form of other devices within the electronic device ED rather than within the display device DD.

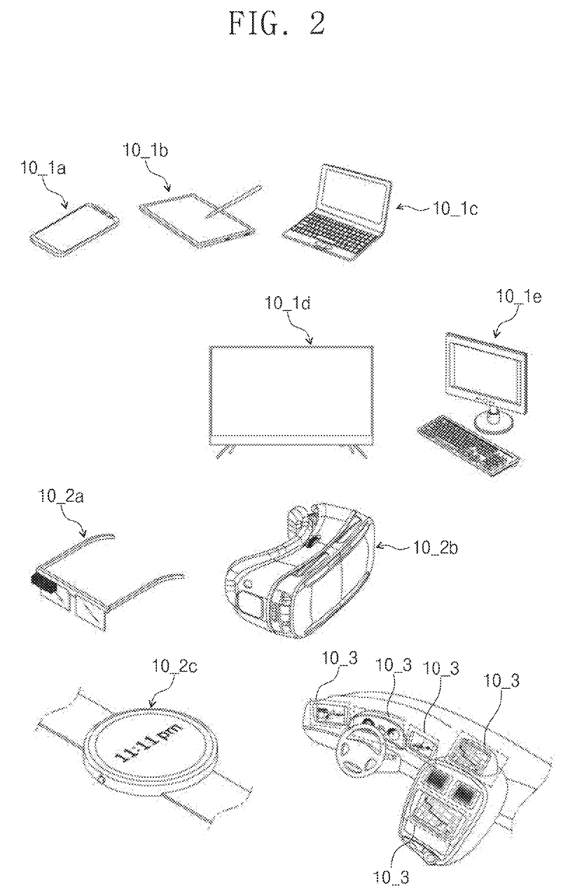

FIG. 2 illustrates schematic diagrams of electronic devices according to one or more embodiments of the present disclosure.

Referring to FIG. 2, the display device DD (see FIG. 1) according to one or more embodiments of the disclosure may be applied to one or more suitable electronic devices. For example, one or more suitable electronic devices to which the display device DD according to one or more embodiments of the disclosure is applied may include, for example, a smart phone 10_1a, a tablet PC 10_1b, a laptop 10_1c, a TV 10_1d, or a desktop monitor 10_1e for displaying images.

In addition, one or more suitable electronic devices to which the display device DD according to one or more embodiments of the disclosure is applied may include wearable electronic devices such as smart glasses 10_2a, a head-mounted display 10_2b, or a smart watch 10_2c. In addition, one or more suitable electronic devices to which the display device DD according to one or more embodiments of the disclosure is applied may include vehicle electronic devices 10_3 such as a center information display (CID) arranged on an instrument cluster, a center fascia, or a dashboard, or a room mirror display of a vehicle.

Hereinafter, as an example, the electronic device ED will be described as a smartphone 10_1a.

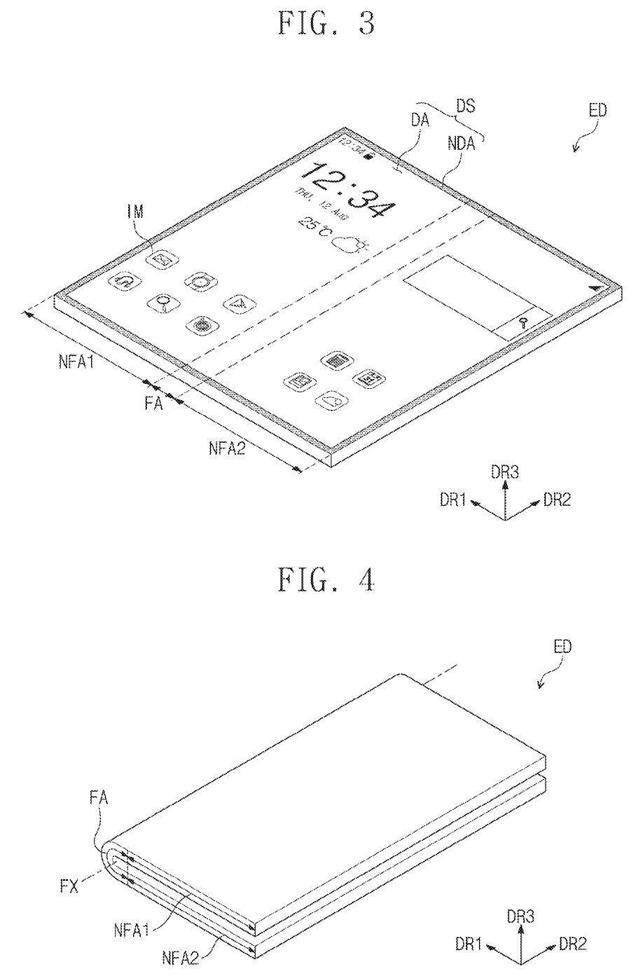

FIG. 3 is a perspective view of an electronic device according to one or more embodiments of the present disclosure. FIG. 4 illustrates a folded state of the electronic device illustrated in FIG. 3 according to one or more embodiments.

Referring to FIG. 3, the electronic device ED according to one or more embodiments of the disclosure may have a rectangular shape having short sides extending in a first direction DR1 and long sides extending in a second direction DR2 crossing the first direction DR1. Without being limited thereto, however, the electronic device ED may have another suitable shape such as a circle and/or a polygon. In one or more embodiments, the electronic device ED may be flexible.

Hereinafter, a direction substantially perpendicular to a plane defined by the first direction DR1 and the second direction DR2 is defined as a third direction DR3. In addition, in this disclosure, the expression "when viewed on a plane" or “in plan view” may be defined as a state viewed from the third direction DR3.

The electronic device ED may include a folding region FA and a plurality of non-folding regions NFA1 and NFA2. The non-folding regions NFA1 and NFA2 may include a first non-folding region NFA1 and a second non-folding region NFA2. The folding region FA may be arranged between the first non-folding region NFA1 and the second non-folding region NFA2. The folding region FA, the first non-folding region NFA1, and the second non-folding region NFA2 may be arranged (e.g., sequentially arranged) in the first direction DR1, for example, in the stated order.

As an example embodiment, one folding region FA and two non-folding regions NFA1 and NFA2 are illustrated, but the number of the folding region FA and the non-folding regions NFA1 and NFA2 is not limited thereto. For example, in one or more embodiments, the electronic device ED may include a plurality of non-folding regions more than two and a plurality of folding regions arranged between the non-folding regions.

An upper surface of the electronic device ED may be defined as a display surface DS, and the display surface DS may have a plane defined by the first direction DR1 and the second direction DR2. Images IM generated in the electronic device ED may be provided to a user through the display surface DS.

The display surface DS may include a display region DA and a non-display region NDA around (e.g., surrounding) the display region DA. The display region DA may display an image IM, and the non-display region NDA may not display an image. The non-display region NDA may define an edge of the electronic device ED that surrounds the display region DA and may have a set or predetermined color.

Referring to FIG. 4, in one or more embodiments, the electronic device ED may be a foldable electronic device ED that can be folded or unfolded. For example, the folding region FA may be bent along a folding axis FX parallel to the second direction DR2 so that the electronic device ED is folded. The folding axis FX may be defined as a long axis parallel to a long side of the electronic device ED. In one or more embodiments, when the electronic device ED is folded, the first non-folding region NFA1 and the second non-folding region NFA2 may face each other, and the electronic device ED may be in-folded so that the display surface DS is not exposed to the outside. However, embodiments of the present disclosure are not limited thereto. For example, in one or more embodiments, the electronic device ED may be out-folded with respect to the folding axis FX so that the display surface DS is exposed to the outside. In one or more embodiments, the electronic device ED may be capable of being in-folded and out-folded.

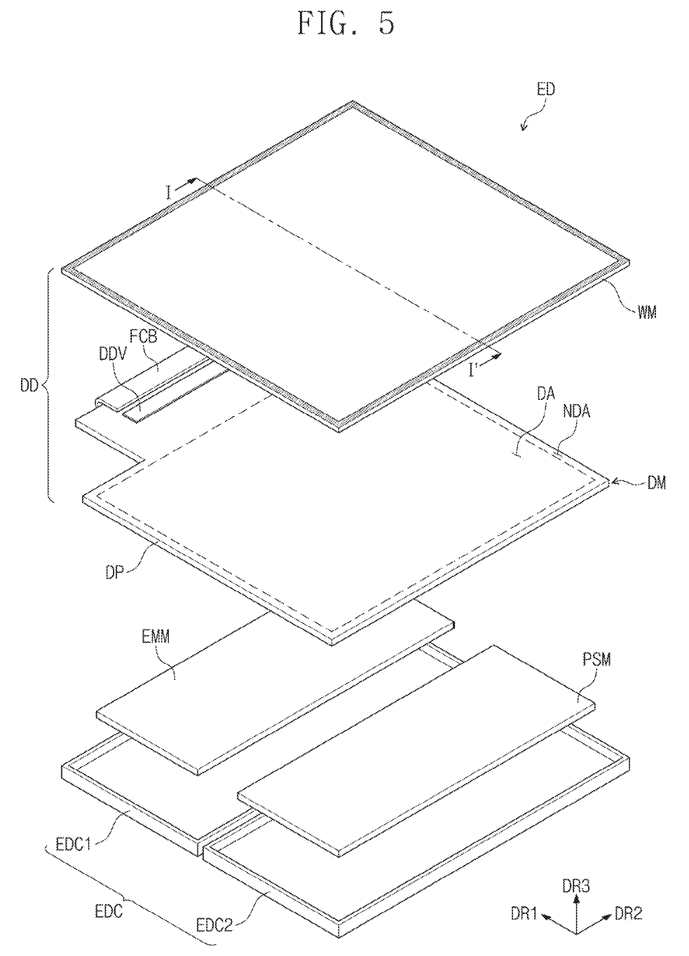

FIG. 5 is an exploded perspective view of the electronic device illustrated in FIG. 3 according to one or more embodiments of the present disclosure.

Referring to FIG. 5, the electronic device ED may include a display device DD, an electronic module EMM, a power module PSM, and a case EDC. Although not illustrated, the electronic device ED may further include a mechanical structure (e.g., a hinge) configured to control the folding operation of the display device DD.

The display device DD may generate an image and sense an external input. The display device DD may include a window module WM and a display module DM. The window module WM may provide a front surface of the electronic device ED. The window module WM may be arranged on the display module DM and protect the display module DM. The window module WM may be to transmit light generated by the display module DM and provide the light to a user.

The display module DM may include a display panel DP. In the stacked structure of the display module DM in FIG. 5, for clarity, only the display panel DP is illustrated, but substantially, the display module DM may further include a plurality of components arranged on upper and lower sides of the display panel DP. The detailed stacked structure of the display module DM will be described in more detail later. The display panel DP may include a display region DA and a non-display region NDA that correspond to the display region DA and the non-display region NDA of the electronic device ED shown in FIG. 3.

The display module DM may include a data driver DDV and a flexible circuit board FCB arranged on the non-display region NDA of the display panel DP. The data driver DDV may be manufactured in the form of an integrated circuit chip and mounted on the non-display region NDA. Without being limited thereto, however, in one or more embodiments, the data driver DDV may be mounted on the flexible circuit board FCB connected to the display panel DP.

The flexible circuit board FCB may be arranged on one side of the display panel DP adjacent to the data driver DDV among two sides (e.g., two opposite sides) of the display panel DP opposite to each other in the first direction DR1. The flexible circuit board FCB may be arranged in the non-display region NDA of the display panel DP. The flexible circuit board FCB may be connected to one side of the display panel DP and bent around a bending axis that extends in the second direction DR1. The bending of the flexible circuit board FCB will be described in more detail later. The flexible circuit board FCB may be electrically connected to the display panel DP.

The electronic module EMM and the power module PSM may be arranged below the display device DD. In one or more embodiments, the electronic module EMM and the power module PSM may be connected to each other through a separate flexible circuit board. The electronic module EMM may control an operation of the display device DD. The power module PSM may supply power to the electronic module EMM.

The case EDC may accommodate the display device DD, the electronic module EMM, and the power module PSM. In one or more embodiments, the case EDC may include first and second cases EDC1 and EDC2 configured to fold the display device DD. The first case EDC1 and the second case EDC2 may each extend in the second direction DR2 and be arranged in the first direction DR1.

In one or more embodiments, the electronic device ED may further include a hinge structure configured to connect the first case EDC1 and the second case EDC2. The case EDC may be coupled to the window module WM. The case EDC may protect the display device DD, the electronic module EMM, and the power module PSM.

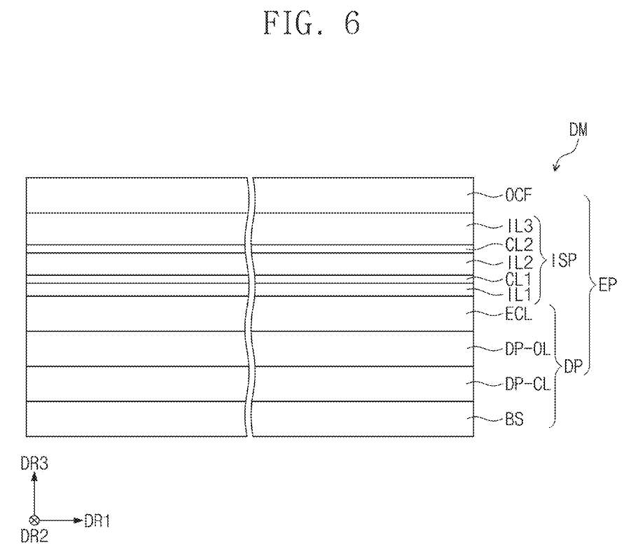

FIG. 6 is a cross-sectional view of a display module DM according to one or more embodiments of the present disclosure.

Referring to FIG. 6, the display module DM may further include an input sensing unit ISP arranged on the display panel DP and an anti-reflection layer OCF arranged on the input sensing unit ISP. For example, in one or more embodiments, the input sensing unit ISP may be arranged directly on the display panel DP. In these embodiments, the expression “the input sensing unit ISP is arranged directly on the display panel DP” refers to that the input sensing unit ISP is formed on the display panel DP through a continuous process so that the input sensing unit ISP and the display panel DP are coupled to each other without a separate adhesive layer. For example, the components of the input sensing unit ISP may be (directly) formed on a base surface provided by the display panel DP.

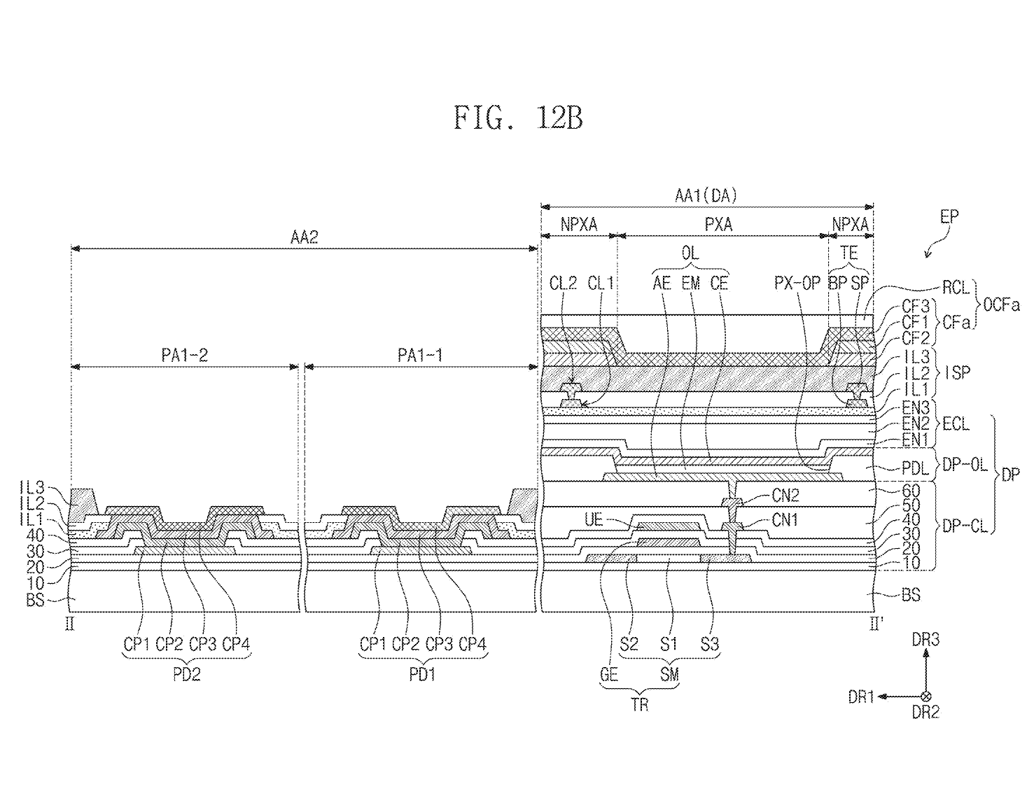

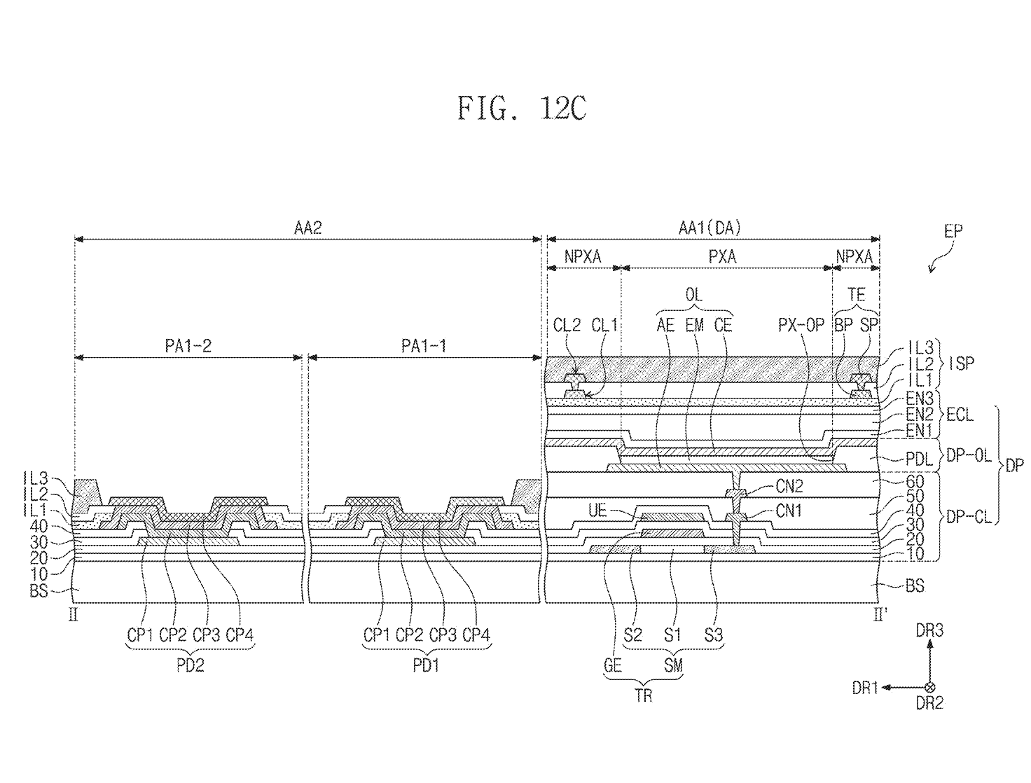

The anti-reflection layer OCF may be arranged on the input sensing unit ISP. The anti-reflection layer OCF may reduce the reflectance of external light. In one or more embodiments, the anti-reflection layer OCF may be arranged directly on the input sensing unit ISP through a continuous process. The anti-reflection layer OCF according to these embodiments may replace a polarizing film. Typically, the polarizing film includes a polyvinyl alcohol film and iodine and/or a dichroic dye arranged on a (e.g., one) surface thereof. The iodine and/or the dichroic dye is arranged in a stretching direction of a stretched polyvinyl alcohol film. The polarizing film increases the thickness of the display device and the manufacturing cost of the display device. The display device according to one or more embodiments may not include (e.g., may exclude) a polarizing film, and the electronic device according to one or more embodiments may not include (e.g., may exclude) a polarizing film that may be arranged inside the display panel, between the display panel and the input sensing unit, between the input sensing unit and the anti-reflection layer, or above (e.g., on) the anti-reflection layer. For example, the electronic device according to these embodiments may not include (e.g., may exclude) a polarizing film that may be arranged inside and outside the display device. In other words, the electronic device according to one or more embodiments, may not include (e.g., may exclude) any polarizing film inside the display panel, between the display panel and the input sensing unit, between the input sensing unit and the anti-reflection layer, or on the anti-reflection layer. The anti-reflection layer OCF will be described in more detail in FIG. 12A.

Hereinafter, the display panel DP, the input sensing unit ISP, and the anti-reflection layer OCF may be defined as an electronic panel EP.

The display panel DP may display an image according to an electrical signal. The display panel DP according to one or more embodiments of the present disclosure may be a light-emitting display panel, but embodiments of the present disclosure are not particularly limited thereto. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, and/or the like. Hereinafter, the display panel DP is described as an organic light-emitting display panel.

The display panel DP may include a base substrate BS, a circuit layer DP-CL, a display element layer DP-OL, and an encapsulation layer ECL sequentially stacked along the third direction DR3 (e.g., thickness direction of the display panel DP).

The base substrate BS may be a rigid substrate or a flexible substrate capable of being bent, folded, or rolled. For example, the base substrate BS may be a glass substrate, a metal substrate, or a polymer substrate. The base substrate BS may provide a base surface on which the circuit layer DP-CL is arranged.

The base substrate BS may include an inorganic layer, an organic layer, or a composite material layer. The base substrate BS may have a single-layer structure or a multi-layer structure. For example, in one or more embodiments, a multi-layer base substrate BS may include synthetic resin layers and a multi-layer or single-layer inorganic layer arranged between the synthetic resin layers. The synthetic resin layer may include an acrylic-based resin, a methacrylic-based resin, polyisoprene, a vinyl-based resin, an epoxy-based resin, a urethane-based resin, a cellulose-based resin, a siloxane-based resin, a polyamide-based resin, and/or a perylene-based resin, but the material of the synthetic resin layer is not limited thereto.

The circuit layer DP-CL may be arranged on the base substrate BS. The circuit layer DP-CL may include at least one insulating layer, a semiconductor pattern, and a conductive pattern. The insulating layer, the semiconductor pattern, and the conductive pattern included in the circuit layer DP-CL may form driving elements such as transistors, signal lines, and pads.

The display element layer DP-OL may be arranged on the circuit layer DP-CL. The display element layer DP-OL may include light-emitting elements, each of which is configured to emit light. For example, the light-emitting element may include an organic light-emitting element, an inorganic light-emitting element, a micro light-emitting diode (LED), a nano LED, and/or the like. The light-emitting elements of the display element layer DP-OL may be electrically connected to the driving elements of the circuit layer DP-CL and emit light according to an electrical signal provided by the driving elements thereof.

The encapsulation layer ECL may be arranged on the display element layer DP-OL to seal the light-emitting elements. The encapsulation layer ECL may include at least one thin film configured to improve the optical efficiency of the display element layer DP-OL and/or protect the display element layer DP-OL. For example, in one or more embodiments, the encapsulation layer ECL may include at least one of an inorganic film or an organic film. The inorganic film of the encapsulation layer ECL may protect the light-emitting elements from moisture/oxygen. The organic film of the encapsulation layer ECL may protect the light-emitting elements from foreign substances such as dust particles.

The input sensing unit ISP may sense an external input and provide an input signal including information about the external input so that the display panel DP may display an image corresponding to the external input. The input sensing unit ISP may be driven in one or more suitable ways such as a capacitive method, a resistive film method, an infrared method, an acoustic wave method, or a pressure method, and the driving method of the input sensing unit ISP is not limited to any particular one as long as it can sense an external input. In one or more embodiments of the present disclosure, the input sensing unit ISP is described as an input sensing panel driven by a capacitive method.

The input sensing unit ISP may include a base layer IL1, a first sensing conductive layer CL1, a first sensing insulating layer IL2, a second sensing conductive layer CL2, and a second sensing insulating layer IL3 sequentially stacked along the third direction DR3. The base layer IL1 of the input sensing unit ISP may be in contact with the encapsulation layer ECL. However, embodiments of the present disclosure are not limited thereto, for example, in one or more embodiments, at least one of the base layer IL1 or the first sensing insulating layer IL2 may not be provided.

Each of the first sensing conductive layer CL1 and the second sensing conductive layer CL2 may have a single-layer structure or a multi-layer structure. In one or more embodiments, the multi-layer conductive layer may include at least two or more selected from among transparent conductive layers and metal layers. In one or more embodiments, the multi-layer conductive layer may include metal layers including different metals. The transparent conductive layer may include at least one of indium tin oxide (ITO), indium zinc oxide (IZO), zinc oxide (ZnO), indium tin zinc oxide (ITZO), poly(3,4-ethylenedioxythiophene) (PEDOT), metal nanowires, or graphene. The metal layer may include at least one of molybdenum, silver, titanium, copper, aluminum, or an alloy thereof. For example, in one or more embodiments, the metal layer may have a three-layer structure of titanium/aluminum/titanium. Without being limited thereto, however, in one or more embodiments, each of the first sensing conductive layer CL1 and the second sensing conductive layer CL2 may have a two-layer structure, for example, a two-layer structure of ITO/copper.

Each of the first sensing conductive layer CL1 and the second sensing conductive layer CL2 may include sensing conductive patterns. The sensing conductive patterns of the first sensing conductive layer CL1 and the second sensing conductive layer CL2 may form sensing electrodes, which constitute the input sensing unit ISP, and sensing lines connected thereto.

Each of the base layer IL1 and the first sensing insulating layer IL2 may include at least one of an inorganic film or an organic film, and the second sensing insulating layer IL3 may include an organic film. For example, the inorganic film may include at least any one of aluminum oxide, titanium oxide, silicon oxide, silicon oxynitride, zirconium oxide, or hafnium oxide, and the organic film may include at least any one of an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin. However, the materials of the inorganic film and the organic film are not limited to the above examples. In one or more embodiments of the disclosure, the base layer IL1 may include an inorganic film, and the first sensing insulating layer IL2 and the second sensing insulating layer IL3 may include an organic film, but embodiments of the disclosure are not limited thereto.

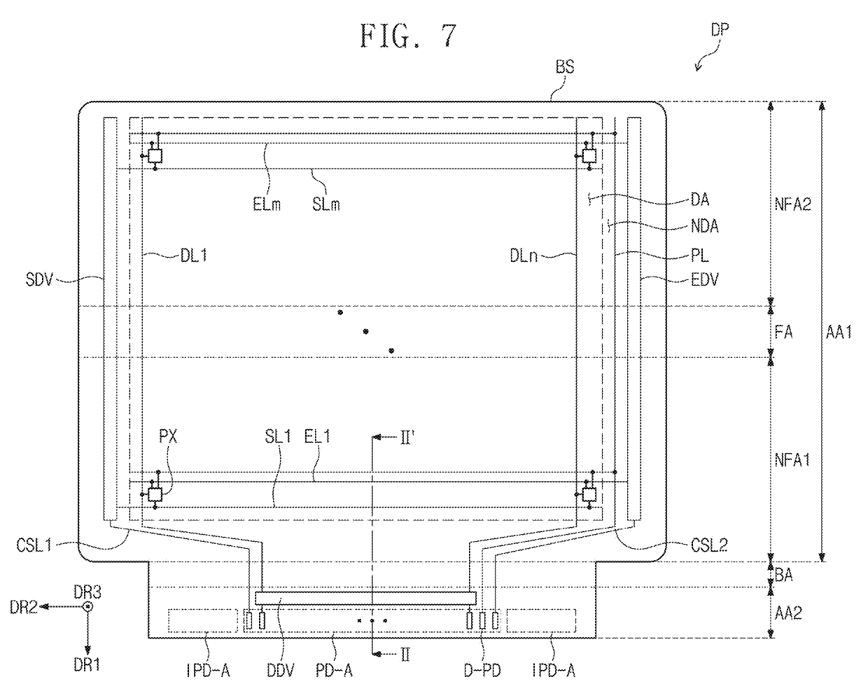

FIG. 7 is a plan view of a display panel according to one or more embodiments of the present disclosure.

Among the components illustrated in FIG. 7, descriptions of the same components as those described with reference to the above-mentioned drawings will not be provided or simplified.

Referring to FIG. 7, the display panel DP may include a base substrate BS, pixels PX, signal lines SL1 to SLm, DL1 to DLn, EL1 to ELm, CSL1, CSL2, and PL electrically connected to the pixels PX, a scan driver SDV, an emission driver EDV, a data driver DDV, and display pads D-PD. The base substrate BS may provide a base surface on which electrical elements, lines, and/or the like of the display panel DP are arranged.

The display panel DP may include a first non-bending portion AA1, a bending portion BA, and a second non-bending portion AA2 that are divided in the first direction DR1. The bending portion BA may extend from the first non-bending portion AA1 in the first direction DR1. The second non-bending portion AA2 may extend from the bending portion BA in the first direction DR1. Accordingly, the first non-bending portion AA1 and the second non-bending portion AA2 may be spaced from (e.g., spaced apart from) each other with the bending portion BA interposed therebetween.

The first non-bending portion AA1 may include a display region DA. The display region DA may be a region in which light-emitting elements of the pixels PX are arranged. Accordingly, the pixels PX may display an image through the display region DA. The display region DA may correspond to the display region DA (see FIG. 5) of the display module DM (see FIG. 5).

When viewed from the second direction DR2, the first non-bending portion AA1 may include a first non-folding region NFA1, a second non-folding region NFA2, and a folding region FA between the first non-folding region NFA1 and the second non-folding region NFA2.

The first non-bending portion AA1, the bending portion BA, and the second non-bending portion AA2 excluding the display region DA may be defined as a non-display region NDA. The non-display region NDA may be adjacent to the display region DA and may be a region in which an image is not displayed. In one or more embodiments, the non-display region NDA may surround the display region DA. In the non-display region NDA, the scan driver SDV, the emission driver EDV, the data driver DDV, which are configured to drive the pixels PX, and the display pads D-PD electrically connected to the signal lines SL1 to SLm, DL1 to DLn, EL1 to ELm, CSL1, CSL2, and PL may be arranged. The signal lines SL1~SLm, DL1~DLn, EL1~ELm, CSL1, CSL2, and PL electrically connected to the pixels PX may extend and be arranged on the non-display region NDA.

The bending portion BA may be a region that is bent around a bending axis extending in the second direction DR2. For example, the bending portion BA may be bent toward a rear surface of the display panel DP corresponding to the first non-bending portion AA1. By the bending of the bending portion BA, the second non-bending portion AA2 extending from one side of the bending portion BA may overlap the first non-bending portion AA1 on a plane. For example, the second non-bending portion AA2 may be arranged on the rear surface of the display panel DP corresponding to the first non-bending portion AA1.

In the second direction DR2, a width of each of the bending portion BA and the second non-bending portion AA2 may be less than a width of the first non-bending portion AA1. Because the bending portion BA has a width less than that of the first non-bending portion AA1 in a direction parallel to the bending axis, the bending portion BA may be easily bent. However, this is illustrated as an example, for example, in the second direction DR2, in one or more embodiments, at least one of the width of the bending portion BA or the width of the second non-bending portion AA2 may be the same as the width of the first non-bending portion AA1, and the present disclosure is not limited to any one specific embodiment.

By the bending of the bending portion BA, the second non-bending portion AA2 may be positioned below the first non-bending portion AA1 and be provided flatly. The second non-bending portion AA2 may be a region in which the data driver DDV and some of the signal lines SL1~SLm, DL1~DLn, EL1~ELm, CSL1, CSL2, and PL extending toward the display pads D-PD via the bending portion BA are arranged.

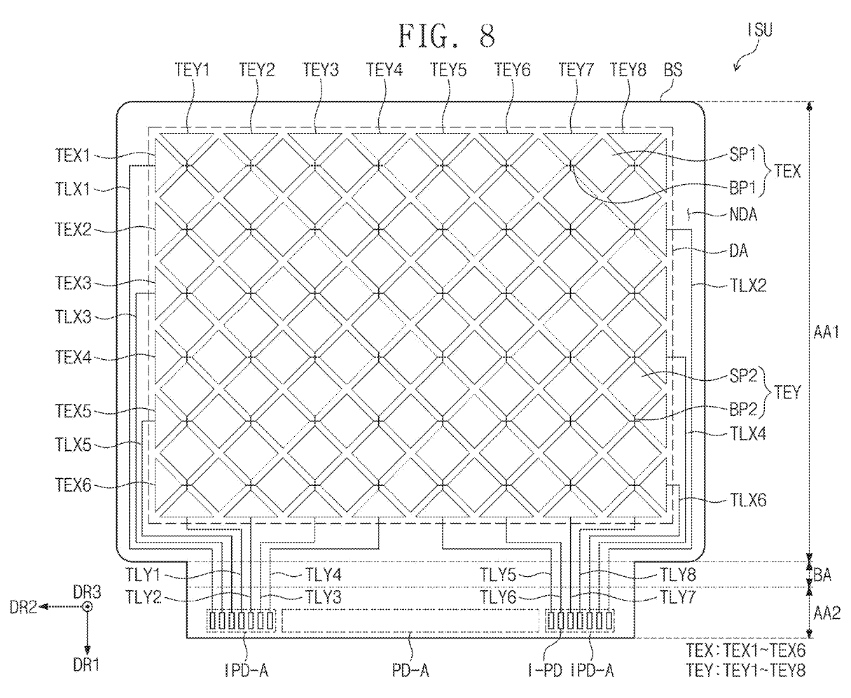

A region in which the display pads D-PD are arranged and a region in which sensing pads I-PD (see FIG. 8) to be described later are arranged may be divided into a display pad region PD-A and a sensing pad region IPD-A, respectively. As an example, FIG. 7 illustrates that the display pad region PD-A and the sensing pad region IPD-A are divided in the second direction DR2. For example, the sensing pad region IPD-A may be provided to be adjacent to both sides (e.g., two opposite sides) of the second non-bending portion AA2 in the second direction DR2, and the display pad region PD-A may be provided in the central portion. However, embodiments of the present disclosure are not necessarily limited thereto, and the arrangement positions of the display pads D-PD and the sensing pads I-PD (see FIG. 8) may be variously changed.

Referring to FIGS. 5 and 7, the flexible circuit board FCB may be arranged on the second non-bending portion AA2, on which the display pads D-PD and the sensing pads I-PD (see FIG. 8) are arranged, and may be electrically connected to the display pads D-PD and the sensing pads I-PD (see FIG. 8). By the bending of the bending portion BA, the flexible circuit board FCB arranged to be adjacent to a lower end of the second non-bending portion AA2 may be positioned on the rear surface of the display panel DP. Because the second non-bending portion AA2 and the flexible circuit board FCB are positioned below the first non-bending portion AA1 on the front surface of the electronic device ED (see FIG. 3), a bezel area of the electronic device ED (see FIG. 3) may be reduced. The bending of the flexible circuit board FCB will be described in more detail later.

Referring to FIG. 7, each of the pixels PX may include a pixel driving circuit, which is composed of transistors (e.g., a switching transistor, a driving transistor, and/or the like) and at least one capacitor, and a light-emitting element electrically connected to the pixel driving circuit. The pixels PX may generate light in response to an electrical signal applied to each of the pixels PX and display an image through the display region DA. According to one or more embodiments of the present disclosure, some of the pixels PX may include a transistor arranged in the non-display region NDA, but the present disclosure is not limited to any one specific embodiment.

The scan driver SDV and the emission driver EDV may be arranged in the non-display region NDA of the first non-bending portion AA1. The data driver DDV may be arranged in the non-display region NDA of the second non-bending portion AA2. In one or more embodiments of the present disclosure, the data driver DDV may be provided in the form of an integrated circuit chip mounted in the non-display region NDA of the display panel DP. Without being limited thereto, however, in one or more embodiments, the data driver DDV may be mounted on the flexible circuit board FCB (see FIG. 5).

The signal lines SL1 to SLm, DL1 to DLn, EL1 to ELm, CSL1, CSL2, and PL may include scan lines SL1 to SLm, data lines DL1 to DLn, light-emitting lines EL1 to ELm, first and second control lines CSL1 and CSL2, and a power line PL, wherein m and n each represent a natural number.

The data lines DL1 to DLn may be insulated from and cross the scan lines SL1 to SLm and the light-emitting lines EL1 to ELm. For example, in one or more embodiments, the scan lines SL1 to SLm may extend in the second direction DR2 and be electrically connected to the scan driver SDV. The data lines DL1 to DLn may extend in the first direction DR1 and be electrically connected to the data driver DDV. The light-emitting lines EL1 to ELm may extend in the second direction DR2 and be electrically connected to the emission driver EDV.

The power line PL may include a portion extending in the first direction DR1 and a portion extending in the second direction DR2. The portion of the power line PL extending in the first direction DR1 and the portion thereof extending in the second direction DR2 may be arranged in different layers or integrally arranged in a same layer as each other. The portion of the power line PL extending in the second direction DR2 may be electrically connected to the pixels PX and the portion thereof extending in the first direction DR1. The portion of the power line PL extending in the first direction DR1 may be arranged in the non-display region NDA and electrically connected to the display pads D-PD via the bending portion BA and the second non-bending portion AA2 from the first non-bending portion AA1. The power line PL may provide a first voltage to the pixels PX.

The first control line CSL1 may be electrically connected to the scan driver SDV and extend toward the lower end of the second non-bending portion AA2 via the bending portion BA. The second control line CSL2 may be electrically connected to the emission driver EDV and extend toward the lower end of the second non-bending portion AA2 via the bending portion BA.

The display pads D-PD may be arranged to be adjacent to the lower end of the second non-bending portion AA2. On the second non-bending portion AA2, the display pads D-PD may be arranged to be closer to a lower end of the base substrate BS than the data driver DDV. The display pads D-PD may be spaced and/or apart (e.g., spaced apart or separated) from each other along the second direction DR2. Each of the power line PL, the first control line CSL1, and the second control line CSL2 may be electrically connected to a corresponding display pad D-PD among the display pads D-PD. Each of the data lines DL1 to DLn may be electrically connected to a corresponding display pad D-PD among the display pads D-PD through the data driver DDV.

The display pads D-PD may be electrically connected to the flexible circuit board FCB (see FIG. 5) through an anisotropic conductive adhesive layer, and an electrical signal provided from the flexible circuit board FCB (see FIG. 5) may be transmitted to the display panel DP through the display pads D-PD. However, the connection method between the display pads D-PD and the flexible circuit board FCB (see FIG. 5) is not particularly limited thereto.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate light-emitting signals in response to a light-emitting control signal. The light-emitting signals may be applied to the pixels PX through the light-emitting lines EL1 to ELm.

The pixels PX may receive the data voltages in response to the scan signals. The pixels PX may generate an image by emitting light with a brightness corresponding to the data voltages in response to the light-emitting signals. The light- emitting time of the pixels PX may be controlled or selected by the light-emitting signals.

FIG. 8 is a plan view of an input sensing unit according to one or more embodiments of the present disclosure.

For convenience of explanation, FIG. 8 briefly illustrates the components of the input sensing unit ISP arranged on the aforementioned base substrate BS (see FIG. 7).

In one or more embodiments of the disclosure, the input sensing unit ISP may be driven by a mutual-cap method.

Referring to FIG. 8, the input sensing unit ISP may include first sensing electrodes TEX: TEX1 to TEX6, second sensing electrodes TEY: TEY1 to TEY8, first sensing lines TLX1 to TLX6, second sensing lines TLY1 to TLY8, and sensing pads I-PD. Without being limited thereto, however, in one or more embodiments, the input sensing unit ISP may be driven by a self-cap method.

Each of the first sensing electrodes TEX may extend along the second direction DR2, and the first sensing electrodes TEX may be arranged along the first direction DR1. FIG. 8 illustrates six first sensing electrodes TEX1 to TEX6 as an example. However, the number of the first sensing electrodes TEX included in the input sensing unit ISP is not limited thereto. One first sensing electrode TEX may include first sensing patterns SP1 arranged along the second direction DR2 and first connection patterns BP1 connecting the first sensing patterns SP1 to each other.

Each of the second sensing electrodes TEY may extend along the first direction DR1, and the second sensing electrodes TEY may be arranged along the second direction DR2. FIG. 8 illustrates eight second sensing electrodes TEY1 to TEY8 as an example. However, the number of the second sensing electrodes TEY included in the input sensing unit ISP is not limited thereto. One second sensing electrode TEY may include second sensing patterns SP2 arranged along the first direction DR1 and second connection patterns BP2 connecting the second sensing patterns SP2 to each other.

The first sensing electrodes TEX and the second sensing electrodes TEY may be electrically insulated from each other. The input sensing unit ISP may sense an external input through a change in capacitance between the first sensing electrodes TEX and the second sensing electrodes TEY. The first sensing electrodes TEX and the second sensing electrodes TEY may be arranged in a region corresponding to the display region DA of the base substrate BS. Accordingly, the electronic device ED (see FIG. 3) may display an image through the display region DA and concurrently (e.g., simultaneously) sense an external input applied to the display region DA.

The first sensing lines TLX1 to TLX6 may be arranged on the non-display region NDA and electrically connected to the first sensing electrodes TEX1 to TEX6, respectively. Some of the first sensing lines TLX1 to TLX6 may be arranged on a left side of the non-display region NDA, and the rest may be arranged on a right side of the non-display region NDA. For example, in one or more embodiments, the first sensing lines TLX1, TLX3, and TLX5 respectively connected to the first sensing electrodes TEX1, TEX3, and TEX5 arranged in odd rows may be connected to the left sides of the first sensing electrodes TEX1, TEX3, and TEX5, respectively, and the first sensing lines TLX2, TLX4, and TLX6 respectively connected to the first sensing electrodes TEX2, TEX4, and TEX6 arranged in even rows may be connected to the right sides of the first sensing electrodes TEX2, TEX4, and TEX6, respectively. However, the arrangement of the first sensing lines TLX1 to TLX6 is not limited thereto, for example, in one or more embodiments, the first sensing lines TLX1 to TLX6 may all be arranged on the left side of the non-display region NDA, or the first sensing lines TLX1 to TLX6 may all be arranged on the right side of the non-display region NDA.

Each of the first sensing lines TLX1 to TLX6 may extend from the first non-bending portion AA1 to the second non-bending portion AA2 via the bending portion BA. The first sensing lines TLX1 to TLX6 may be respectively electrically connected to the sensing pads I-PD arranged on the second non-bending portion AA2.

The second sensing lines TLY1 to TLY8 may be arranged on the non-display region NDA and electrically connected to the second sensing electrodes TEY1 to TEY8, respectively. Some of the second sensing lines TLY1 to TLY8 may be arranged to be adjacent to the left side of the non-display region NDA, and the rest may be arranged to be adjacent to the right side of the non-display region NDA. For example, in one or more embodiments, in the first direction DR1, the second sensing lines TLY1, TLY2, TLY3, and TLY4 electrically connected to the second sensing electrodes TEY1, TEY2, TEY3, and TEY4, respectively, arranged on the left side among the second sensing electrodes TEY1 to TEY8 may be arranged to be adjacent to the left side of the first non-bending portion AA1, and the second sensing lines TLY5, TLY6, TLY7, and TLY8 electrically connected to the second sensing electrodes TEY5, TEY6, TEY7, and TEY8, respectively, arranged on the right side among the second sensing electrodes TEY1 to TEY8 may be arranged to be adjacent to the right side of the first non-bending portion AA1. However, the arrangement of the second sensing lines TLY1 to TLY8 is not limited thereto.

Each of the second sensing lines TLY1 to TLY8 may extend from a region adjacent to a lower end of the first non-bending portion AA1 to the second non-bending portion AA2 via the bending portion BA. The second sensing lines TLY1 to TLY8 may be respectively electrically connected to the sensing pads I-PD arranged on the second non-bending portion AA2.

Some of the sensing pads I-PD may be arranged in a region adjacent to a left side of the second non-bending portion AA2 in the second direction DR2, and the rest may be arranged in a region adjacent to a right side of the second non-bending portion AA2. For example, the sensing pads I-PD may be divided into two groups spaced and/or apart (e.g., spaced apart or separated) from each other with the display pad region PD-A interposed therebetween. However, the arrangement of the sensing pads I-PD is not limited thereto.

The sensing pads I-PD may be arranged in a same layer as the display pads D-PD (see FIG. 7). The sensing pads I-PD may be arranged in a layer different from those of the first and second sensing lines TLX1 to TLX6 and TLY1 to TLY8 and connected thereto through contact holes. Without being limited thereto, however, in one or more embodiments, the sensing pads I-PD may be arranged in a layer different from that of the display pads D-PD (see FIG. 7). For example, the sensing pads I-PD may be integrally formed in a same layer as the first and second sensing lines TLX1 to TLX6 and TLY1 to TLY8.

The first and second sensing lines TLX1 to TLX6 and TLY1 to TLY8 may be arranged above the components of the display panel DP (see FIG. 7) on a region corresponding to the non-display region NDA of the base substrate BS. Accordingly, the first and second sensing lines TLX1 to TLX6 and TLY1 to TLY8 may overlap the components of the display panel DP (see FIG. 7) on the bending portion BA and the second non-bending portion AA2.

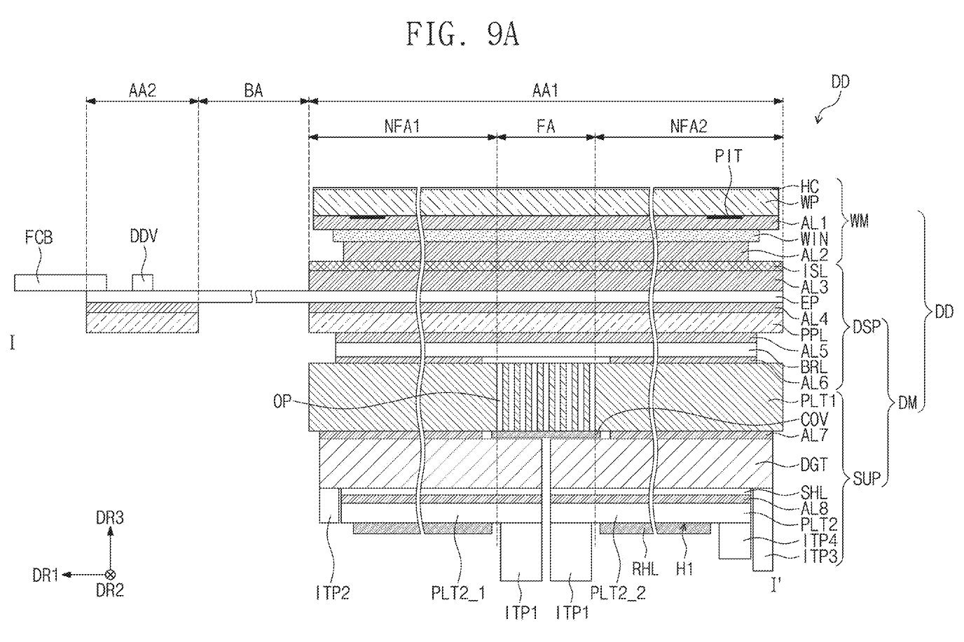

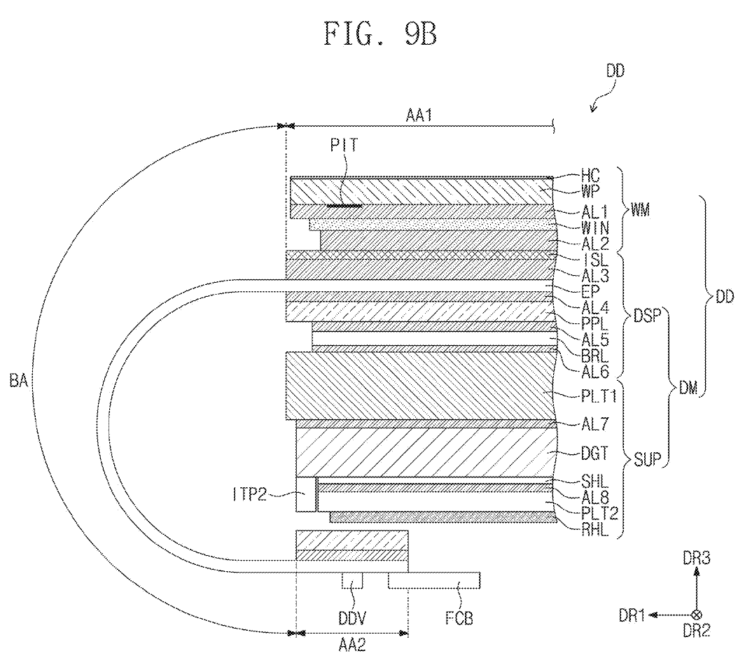

FIG. 9A is a cross-sectional view of the display device corresponding to the line I-I' illustrated in FIG. 5 according to one or more embodiments of the present disclosure. FIG. 9B illustrates a state in which a bending region illustrated in FIG. 9A is bent according to one or more embodiments.

As an example embodiment, in FIG. 9A, a cross section of the display module DM and a cross section of the window module WM, which correspond to the line I-I' of FIG. 5, are illustrated together.

As an example embodiment, FIGS. 9A and 9B illustrate cross-sectional views of the display module DM and the window module WM in a state of being bonded to each other.

Among the components illustrated in FIGS. 9A and 9B, descriptions of the same components as those described with reference to the above-mentioned drawings will not be provided or simplified.

Referring to FIG. 9A, the display device DD may include a display module DM and a window module WM arranged on the display module DM. The display module DM may be a flexible display module. The display module DM may include a first non-folding region NFA1, a folding region FA, and a second non-folding region NFA2.

The display module DM may include a display portion DSP and a support portion SUP. The support portion SUP may be arranged below and support the display portion DSP.

The window module WM may include a window WIN, a window protection layer WP, a hard coating layer HC, and first and second adhesive layers AL1 and AL2. The display portion DSP may include an electronic panel EP, an impact-absorbing layer ISL, a panel protection layer PPL, a barrier layer BRL, and third to sixth adhesive layers AL3 to AL6. The configuration of the electronic panel EP has been described in detail in FIG. 6 above, so the description thereof is not repeated herein.

The impact-absorbing layer ISL may be arranged on the electronic panel EP. The impact-absorbing layer ISL may be to absorb an external impact applied from above the display device DD toward the electronic panel EP to protect the electronic panel EP. The impact-absorbing layer ISL may be manufactured in the form of a stretched film.

The impact-absorbing layer ISL may include a flexible plastic material. The flexible plastic material may be defined as a synthetic resin film. For example, in one or more embodiments, the impact-absorbing layer ISL may include a flexible plastic material such as polyimide (PI) or polyethylene terephthalate (PET).

The window WIN may be arranged on the impact-absorbing layer ISL. The window WIN may protect the electronic panel EP from external scratches. The window WIN may have an optically transparent property. In one or more embodiments, the window WIN may include glass. Without being limited thereto, however, in one or more other embodiments, the window WIN may include a synthetic resin film.

The window WIN may have a multi-layer structure or a single-layer structure. For example, in one or more embodiments, the window WIN may include a plurality of synthetic resin films bonded to each other by an adhesive, or may include a glass substrate and a synthetic resin film bonded to each other by an adhesive.

The window protection layer WP may be arranged on the window WIN. The window protection layer WP may include a flexible plastic material such as polyimide or polyethylene terephthalate. The hard coating layer HC may be arranged on an upper surface of the window protection layer WP.

A printing layer PIT may be arranged on a lower surface of the window protection layer WP. In one or more embodiments, the printing layer PIT may have a black color, but the color of the printing layer PIT is not limited thereto. The printing layer PIT may be adjacent to an edge of the window protection layer WP.

The barrier layer BRL may be arranged below the panel protection layer PPL. The barrier layer BRL may increase resistance to compressive force caused by external pressure. Therefore, the barrier layer BRL may serve to prevent or reduce deformation of the electronic panel EP. The barrier layer BRL may include a flexible plastic material such as polyimide or polyethylene terephthalate.

The barrier layer BRL may have a color that absorbs light. For example, in one or more embodiments, the barrier layer BRL may have a black color. In this regard, if (e.g., when) the display module DM is viewed from above the display module DM, components arranged below the barrier layer BRL may not be visible.

The first adhesive layer AL1 may be arranged between the window protection layer WP and the window WIN. The window protection layer WP and the window WIN may be bonded to each other by the first adhesive layer AL1. The first adhesive layer AL1 may cover the printing layer PIT.

The second adhesive layer AL2 may be arranged between the window WIN and the impact-absorbing layer ISL. The window WIN and the impact-absorbing layer ISL may be bonded to each other by the second adhesive layer AL2.

The third adhesive layer AL3 may be arranged between the impact-absorbing layer ISL and the electronic panel EP. The impact-absorbing layer ISL and the electronic panel EP may be bonded to each other by the third adhesive layer AL3.

The fourth adhesive layer AL4 may be arranged between the electronic panel EP and the panel protection layer PPL. The electronic panel EP and the panel protection layer PPL may be bonded to each other by the fourth adhesive layer AL4.

The fifth adhesive layer AL5 may be arranged between the panel protection layer PPL and the barrier layer BRL. The panel protection layer PPL and the barrier layer BRL may be bonded to each other by the fifth adhesive layer AL5.

The sixth adhesive layer AL6 may be arranged between the barrier layer BRL and the support portion SUP. For example, a first support plate PLT1 of the support portion SUP may be arranged below the barrier layer BRL, and the sixth adhesive layer AL6 may be arranged between the barrier layer BRL and the first support plate PLT1. The barrier layer BRL and the first support plate PLT1 may be bonded to each other by the sixth adhesive layer AL6.

Hereinafter, in this disclosure, the term "thickness" may represent a value or a length measured in the third direction DR3, and the term "width" may represent a value or a length measured in the first direction DR1 or the second direction DR2, which is a horizontal direction.

The sixth adhesive layer AL6 may overlap the first and second non-folding regions NFA1 and NFA2 and may not overlap the folding region FA. For example, the sixth adhesive layer AL6 may not be arranged in the folding region FA.

The first to sixth adhesive layers AL1 to AL6 may each include a transparent adhesive such as a pressure sensitive adhesive (PSA) or an optically clear adhesive (OCA), but the type (kind) of adhesive is not limited thereto.

A thickness of the panel protection layer PPL may be less than a thickness of the window protection layer WP, and a thickness of the barrier layer BRL may be less than the thickness of the panel protection layer PPL. A thickness of the electronic panel EP may be less than the thickness of the barrier layer BRL and equal to a thickness of the window WIN. A thickness of the impact-absorbing layer ISL may be less than the thickness of the electronic panel EP.

A thickness of the first adhesive layer AL1 may be substantially the same as the thickness of the barrier layer BRL, and a thickness of each of the second adhesive layer AL2 and the third adhesive layer AL3 may be substantially the same as the thickness of the panel protection layer PPL. A thickness of the fourth adhesive layer AL4 may be substantially the same as a thickness of the fifth adhesive layer AL5.

The thickness of each of the fourth adhesive layer AL4 and the fifth adhesive layer AL5 may be less than the thickness of the electronic panel EP and greater than the thickness of the impact-absorbing layer ISL. A thickness of the sixth adhesive layer AL6 may be less than the thickness of the impact-absorbing layer ISL. A thickness of the hard coating layer HC may be less than the thickness of the sixth adhesive layer AL6.

The electronic panel EP, the impact-absorbing layer ISL, the panel protection layer PPL, and the third and fourth adhesive layers AL3 and AL4 may have a same width as each other. The window protection layer WP and the first adhesive layer AL1 may have a same width as each other. The barrier layer BRL and the fifth and sixth adhesive layers AL5 and AL6 may have a same width as each other.

Widths of the electronic panel EP, the impact-absorbing layer ISL, the panel protection layer PPL, and the third and fourth adhesive layers AL3 and AL4 may all be greater than widths of the window protection layer WP and the first adhesive layer AL1. Edges of the electronic panel EP, the impact-absorbing layer ISL, the panel protection layer PPL, and the third and fourth adhesive layers AL3 and AL4 may be arranged further outward than edges of the window protection layer WP and the first adhesive layer AL1.

Widths of the window WIN and the second adhesive layer AL2 may be less than the widths of the window protection layer WP and the first adhesive layer AL1. The width of the second adhesive layer AL2 may be less than the width of the window WIN. An edge of the window WIN may be arranged further inward than the edges of the window protection layer WP and the first adhesive layer AL1. An edge of the second adhesive layer AL2 may be arranged further inward than the edge of the window WIN. Here, for example, “further inward” refers to a position closer to the central axis of the display panel in plan view, such that the outer boundaries of the window and the second adhesive layer are recessed relative to the outer boundaries of the window protection layer and the first adhesive layer.

Widths of the barrier layer BRL and the fifth and sixth adhesive layers AL5 and AL6 may be less than the widths of the window protection layer WP and the first adhesive layer AL1. Edges of the barrier layer BRL and the fifth and sixth adhesive layers AL5 and AL6 may be arranged further inward than the edges of the window protection layer WP and the first adhesive layer AL1. Here, for example, “further inward” refers to a position closer to the central region of the display panel in plan view, such that the outer boundaries of the barrier layer and adhesive layers are located within the perimeter defined by the window protection layer and the first adhesive layer.

The support portion SUP may include the first support plate PLT1, a second support plate PLT2, a cover layer COV, a digitizer DGT, a shielding layer SHL, a heat dissipation layer RHL, seventh and eighth adhesive layers AL7 and AL8, and a plurality of first to fourth insulating tapes ITP1 to ITP4.

The first support plate PLT1 may be arranged below and support the electronic panel EP. The first support plate PLT1 may have a stiffness greater than that of the display portion DSP. The first support plate PLT1 may include a non-metallic material. For example, in one or more embodiments, the first support plate PLT1 may include a reinforced fiber composite. The reinforced fiber composite may be carbon fiber reinforced plastic (CFRP) or glass fiber reinforced plastic (GFRP).

The first support plate PLT1 may be lightweight by including a reinforced fiber composite. By including the reinforced fiber composite, the first support plate PLT1 according to one or more embodiments of the present disclosure may have a lighter weight compared to a metal support plate using a metallic material, while having a modulus and strength similar to those of the metal support plate. For example, the reinforced fiber composite allows the first support plate PLT1 to be lighter than a comparable metal support plate formed of a metallic material, while maintaining the modulus and mechanical strength comparable to that of the metal support plate.

In addition, because the first support plate PLT1 includes the reinforced fiber composite, a shape processing of the first support plate PLT1 may be easy compared to the metal support plate. For example, the first support plate PLT1 including the reinforced fiber composite may be more easily processed through a laser process or a micro-blast process.

A plurality of openings OP may be defined in a portion of the first support plate PLT1 overlapping the folding region FA. The openings OP may be formed by passing through portions of the first support plate PLT1 in the third direction DR3. The openings OP may be formed through the aforementioned laser process or micro-blast process.

Because the openings OP are defined in a portion of the first support plate PLT1 overlapping the folding region FA, the flexibility of the portion of the first support plate PLT1 overlapping the folding region FA may be increased. As a result, the first support plate PLT1 may be easily folded around the folding region FA. A width of the portion in which the openings OP are formed may be less than a width of an opened portion of the sixth adhesive layer AL6.

The cover layer COV may be arranged below the first support plate PLT1. The cover layer COV arranged below the first support plate PLT1 may cover the openings OP defined in the first support plate PLT1. The cover layer COV may overlap the folding region FA and may not overlap the first and second non-folding regions NFA1 and NFA2. For example, the cover layer COV may not be arranged in the first and second non-folding regions NFA1 and NFA2. The cover layer COV may be in contact with a lower surface of the portion of the first support plate PLT1, in which the openings OP are formed.

The cover layer COV may have a lower elastic modulus than the first support plate PLT1. For example, in one or more embodiments, the cover layer COV may include thermoplastic polyurethane or a rubber, but the material of the cover layer COV is not limited thereto. The cover layer COV may be manufactured in the form of a sheet and attached to the first support plate PLT1.

The digitizer DGT may be arranged below the first support plate PLT1. The cover layer COV may be arranged between the first support plate PLT1 and the digitizer DGT. The cover layer COV may be spaced and/or apart (e.g., spaced apart or separated) from an upper surface of the digitizer DGT.

The digitizer DGT is a device capable of receiving position information indicated by a user on a display surface. The digitizer DGT may be implemented in an electromagnetic method (or electromagnetic resonance method). For example, in one or more embodiments, the digitizer DGT may include a digitizer sensor substrate including a plurality of coils. Without being limited thereto, however, in one or more embodiments, the digitizer DGT may also be implemented in an active electrostatic method.

When a user moves a pen on the display device DD, the pen is driven by an alternating current signal to generate an oscillating magnetic field, and the oscillating magnetic field may induce a signal in the coil. The position of the pen may be detected based on the signal induced in the coil. The digitizer DGT may determine the position of the pen by sensing electromagnetic changes caused by an approach of the pen.

If (e.g., when) the first support plate PLT1 arranged on and adjacent to the digitizer DGT includes a metal, the sensitivity of the digitizer DGT may be reduced by the metal. For example, if (e.g., when) a signal transmitted on the display device DD is blocked due to signal interference caused by the metal support plate, the digitizer DGT may not operate normally. However, in embodiments of the present disclosure, because the first support plate PLT1 arranged on the digitizer DGT includes a non-metallic reinforced fiber composite, the digitizer DGT may operate normally.

The digitizer DGT may be separated into two portions in the folding region FA. Portions of the digitizer DGT separated from each other may be connected to a digitizer driver through flexible circuit boards, respectively.

The shielding layer SHL may be arranged below the digitizer DGT. The shielding layer SHL may include a metal. For example, in one or more embodiments, the shielding layer SHL may include copper, but the metallic material of the shielding layer SHL is not limited thereto. The shielding layer SHL may be separated into two portions in the folding region FA. Portions of the shielding layer SHL separated from each other may be respectively arranged below the portions of the digitizer DGT separated from each other.

The shielding layer SHL may shield electromagnetic fields that is applied to the digitizer DGT below the display device DD. The shielding layer SHL may also be defined as an electromagnetic shielding layer. The shielding layer SHL including metal may also serve as a heat dissipation layer.

The second support plate PLT2 may be arranged below the shielding layer SHL. The second support plate PLT2 may have a rigidity greater than that of the display portion DSP. The second support plate PLT2 may include a metallic material such as stainless steel (for example, SUS 316), but the metallic material of the second support plate PLT2 is not limited thereto. In one or more embodiments, the second support plate PLT2 may include a non-metallic material such as plastic.

The second support plate PLT2 may be separated into two portions in the folding region FA. For example, in one or more embodiments, the second support plate PLT2 may include a (2-1)-th support plate PLT2_1 overlapping the first non-folding region NFA1 and a (2-2)-th support plate PLT2_2 overlapping the second non-folding region NFA2.

The (2-1)-th support plate PLT2_1 may support the first non-folding region NFA1. The (2-2)-th support plate PLT2_2 may support the second non-folding region NFA2. The (2-1)-th support plate PLT2_1 and the (2-2)-th support plate PLT2_2 may extend to the folding region FA and be arranged to be adjacent to each other in the folding region FA.

The (2-1)-th support plate PLT2_1 and the (2-2)-th support plate PLT2_2 may be spaced and/or apart (e.g., spaced apart or separated) from each other in the folding region FA. The (2-1)-th support plate PLT2_1 and the (2-2)-th support plate PLT2_2 may support a portion of the first support plate PLT1 in which the openings OP are defined in the folding region FA. When pressure is applied to the first support plate PLT1 from above, deformation of the portion of the first support plate PLT1 in which the openings OP are defined may be prevented or reduced by the (2-1)-th support plate PLT2_1 and the (2-2)-th support plate PLT2_2. In addition, the (2-1)-th and (2-2)-th support plates PLT2_1 and PLT2_2 may perform a heat dissipation function.

The heat dissipation layer RHL may be arranged below the second support plate PLT2. The heat dissipation layer RHL may be separated into two portions in the folding region FA. Portions of the heat dissipation layer RHL separated from each other may be arranged below the (2-1)-th and (2-2)-th support plates PLT2_1, PLT2_2), respectively.

The heat dissipation layer RHL may perform a heat dissipation function. For example, in one or more embodiments, the heat dissipation layer RHL may include graphite, but the material of the heat dissipation layer RHL is not limited thereto. Because the heat dissipation layer RHL performs a heat dissipation function together with the second support plate PLT2 and the shielding layer SHL, the heat dissipation performance of the display device DD may be improved.

The first to fourth insulating tapes ITP1 to ITP4 may be arranged below the digitizer DGT and the second support plate PLT2. The first to fourth insulating tapes ITP1 to ITP4 may each include an insulating material.

Two first insulating tapes ITP1 may be respectively arranged below the (2-1)-th and (2-2)-th support plates PLT2_1 and PLT2_2 adjacent to one side of the (2-1)-th support plate PLT2_1 and one side of the (2-2)-th support plate PLT2_2 that face each other.

The second insulating tape ITP2 and the third insulating tape ITP3 may be respectively arranged to be adjacent to both sides (e.g., two opposite sides) of the digitizer DGT below the digitizer DGT. The second insulating tape ITP2 may be adjacent to an edge of the (2-1)-th support plate PLT2_1, and the third insulating tape ITP3 may be adjacent to an edge of the (2-2)-th support plate PLT2_2.

The fourth insulating tape ITP4 may be adjacent to the other side of the (2-2)-th support plate PLT2_2 opposite to the one side of the (2-2)-th support plate PLT2_2. The fourth insulating tape ITP4 may be arranged below the (2-2)-th support plate PLT2_2.

The shielding layer SHL, the second support plate PLT2, the heat dissipation layer RHL, the first insulating tapes ITP1, and the fourth insulating tape ITP4 may be arranged between the second insulating tape ITP2 and the third insulating tape ITP3. One of the heat dissipation layers RHL separated from each other may be arranged between the first insulating tape ITP1 and the fourth insulating tape ITP4 arranged below the (2-2)-th support plate PLT2_2. The other one of the heat dissipation layers RHL separated from each other may be arranged between the first insulating tape ITP1 arranged below the (2-1)-th support plate PLT2_1 and the second insulating tape ITP2 arranged below the digitizer DGT.

In one or more embodiments, magnets may be arranged below the display module DM to maintain a folded state if (e.g., when) the electronic device ED is folded. The magnets may be adjacent to an edge of the electronic device ED. The folded state of the electronic device ED may be maintained by the magnetic force of the magnets.

When the magnetism of the magnets is transmitted to the digitizer DGT, the digitizer DGT may not operate normally. The first to fourth insulating tapes ITP1 to ITP4 may block the magnetism of the magnets arranged on the edge of the electronic device ED from being transmitted to the digitizer DGT. The first to fourth insulating tapes ITP1 to ITP4 may be defined as magnetic shielding tapes.

The seventh adhesive layer AL7 may be arranged between the first support plate PLT1 and the digitizer DGT. The first support plate PLT1 and the digitizer DGT may be bonded to each other by the seventh adhesive layer AL7. The seventh adhesive layer AL7 may not be arranged in the folding region FA. For example, the seventh adhesive layer AL7 may be opened in the folding region FA. The cover layer COV described above may be arranged in the opening of the seventh adhesive layer AL7. Because the seventh adhesive layer AL7 is not arranged in the folding region FA, the folding operation of the support portion SUP may be performed more easily.

The eighth adhesive layer AL8 may be arranged between the shielding layer SHL and the second support plate PLT2. The shielding layer SHL and the second support plate PLT2 may be bonded to each other by the eighth adhesive layer AL8. The eighth adhesive layer AL8 may be separable into two portions in the folding region FA. The two separated portions of the eighth adhesive layer AL8 may be respectively arranged between the two separated portions of the shielding layer SHL and the (2-1)-th and (2-2)-th support plates PLT2_1 and PLT2_2. The eighth adhesive layer AL8 may be arranged between the second insulating tape ITP2 and the third insulating tape ITP3.

A width of the first supporting plate PLT1 may be substantially the same as a width of the electronic panel EP. Widths of the digitizer DGT and the seventh adhesive layer AL7 may be less than the width of the first supporting plate PLT1. Edges of the digitizer DGT and the seventh adhesive layer AL7 may each be arranged further inward than an edge of the first support plate PLT1. Here, for example, “further inward” refers to a position closer to the center of the electronic panel in plan view, such that the outer boundaries of the digitizer and the seventh adhesive layer are located within the perimeter defined by the first support plate.

Widths of the shielding layer SHL, the eighth adhesive layer AL8, and the second support plate PLT2 may be less than the width of the digitizer DGT. Edges of the shielding layer SHL, the eighth adhesive layer AL8, and the second support plate PLT2 may each be arranged further inward than the edge of the digitizer DGT. Here, for example, “further inward” refers to a position closer to the central region of the electronic panel in plan view, such that the outer boundaries of the shielding layer, the eighth adhesive layer, and the second support plate are located within the perimeter defined by the digitizer.

A thickness of the first support plate PLT1 may be greater than a thickness of the digitizer DGT, and the thickness of the digitizer DGT may be greater than a thickness of the second support plate PLT2. The thickness of the second support plate PLT2 may be greater than a thickness of the heat dissipation layer RHL, and the thickness of the heat dissipation layer RHL may be greater than a thickness of each of the seventh and eighth adhesive layers AL7 and AL8.

The thickness of each of the seventh and eighth adhesive layers AL7 and AL8 may be greater than a thickness of the shielding layer SHL, and the thickness of the shielding layer SHL may be greater than a thickness of the cover layer COV. The thickness of the cover layer COV may be equal to the thickness of the sixth adhesive layer AL6.

A thickness of each of the first insulating tapes ITP1 may be less than the thickness of the first support plate PLT1 and greater than the thickness of the digitizer DGT. A thickness of the third insulating tape ITP3 may be greater than the thickness of the first support plate PLT1. A thickness of the fourth insulating tape ITP4 may be less than the thickness of each of the first insulating tapes ITP1. A thickness of the second insulating tape ITP2 may be less than the thickness of the fourth insulating tape ITP4.

The seventh and eighth adhesive layers AL7 and AL8 may each include a pressure sensitive adhesive (PSA) or an optically clear adhesive (OCA), but the type (kind) of adhesive is not limited thereto.

Referring to FIG. 9B, the panel protection layer PPL and the fourth adhesive layer AL4 may not be arranged below the bending portion BA. The panel protection layer PPL and the fourth adhesive layer AL4 may be arranged below the second non-bending portion AA2 of the electronic panel EP. The data driver DDV may be arranged on the second non-bending portion AA2 of the electronic panel EP.

The flexible circuit board FCB may be connected to the second non-bending portion AA2 of the electronic panel EP. The flexible circuit board FCB may be connected to one side of the second non-bending portion AA2. The bending portion BA may be bent so that the second non-bending portion AA2 may be arranged below the first non-bending portion AA1. Accordingly, the data driver DDV and the flexible circuit board FCB may be arranged below the first non-bending portion AA1.

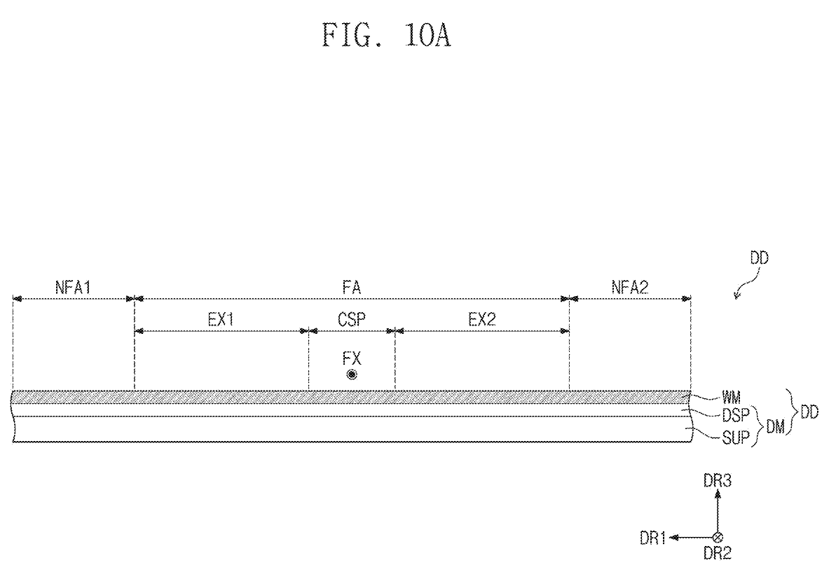

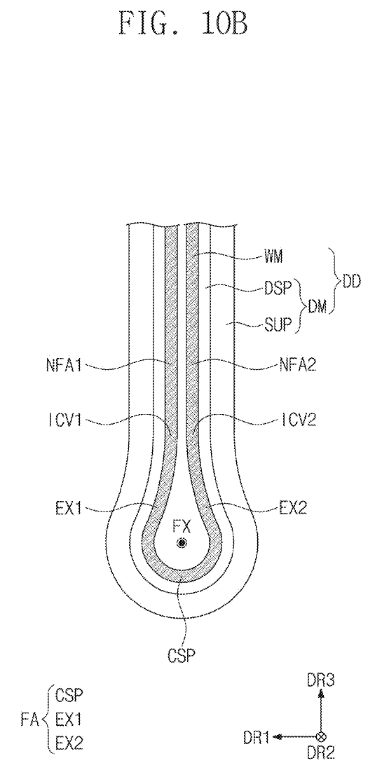

FIG. 10A is a cross-sectional view of the window module and the display module illustrated in FIG. 9A according to one or more embodiments of the present disclosure. FIG. 10B is a cross-sectional view for explaining a folded state of the window module and the display module according to one or more embodiments.

For example, FIGS. 10A and 10B are cross-sectional views viewed from the second direction DR2.

For convenience of explanation, the window module WM, the display portion DSP, and the support portion SUP are simply illustrated as one layer each.

For convenience of explanation and for clarity, the openings OP (see FIG. 9A) defined in the support portion SUP are omitted.

Among the components illustrated in FIGS. 10A and 10B, descriptions of the same components as those described with reference to the above-mentioned drawings will not be provided or simplified.

Referring to FIG. 10A, the folding region FA may include a curved portion CSP and extension portions EX1 and EX2. The extension portions EX1 and EX2 may be arranged between the curved portion CSP and the first non-folding region NFA1 and between the curved portion CSP and the second non-folding region NFA2, respectively. The folding axis FX may overlap the curved portion CSP.

Referring to FIGS. 10A and 10B, if (e.g., when) the folding region FA is folded around the folding axis FX, the display module DM and the window module WM may be folded. The folding region FA may be bent so that the display module DM and the window module WM can be folded. The first non-folding region NFA1 and the second non-folding region NFA2 may rotate around the folding axis FX to face each other. When the folding region FA is folded, the folding region FA may be bent into a curved shape. When the folding region FA is bent into a curved shape, portions of the display module DM and the window module WM may be bent into a curved shape.

When the folding region FA is bent into a curved shape, a portion overlapping the folding axis FX may have a set or predetermined curvature. When the display device DD is folded, the curved portion CSP may be bent to have a set or predetermined curvature. For example, the curved portion CSP may be bent to have a set or predetermined radius of curvature. Portions of the display module DM and the window module WM arranged on the curved portion CSP may have a set or predetermined curvature.

Portions of the display module DM and the window module WM between a first extension portion EX1 and the first non-folding region NFA1 may be bent. The first extension portion EX1 may be bent from the first non-folding region NFA1 and extend to the curved portion CSP.

Portions of the display module DM and the window module WM between the second extension portion EX2 and the second non-folding region NFA2 may be bent. The second extension portion EX2 may be bent from the second non-folding region NFA2 and extend to the curved portion CSP.

The curved portion of the display device DD between the first extension portion EX1 and the first non-folding region NFA1 may be defined as a first reverse curvature portion ICV1. The curved portion of the display device DD between the second extension portion EX2 and the second non-folding region NFA2 may be defined as a second reverse curvature portion ICV2. When the display device DD is folded, the first reverse curvature portion ICV1 and the second reverse curvature portion ICV2 may each be bent in a direction opposite to that of the curved portion CSP.

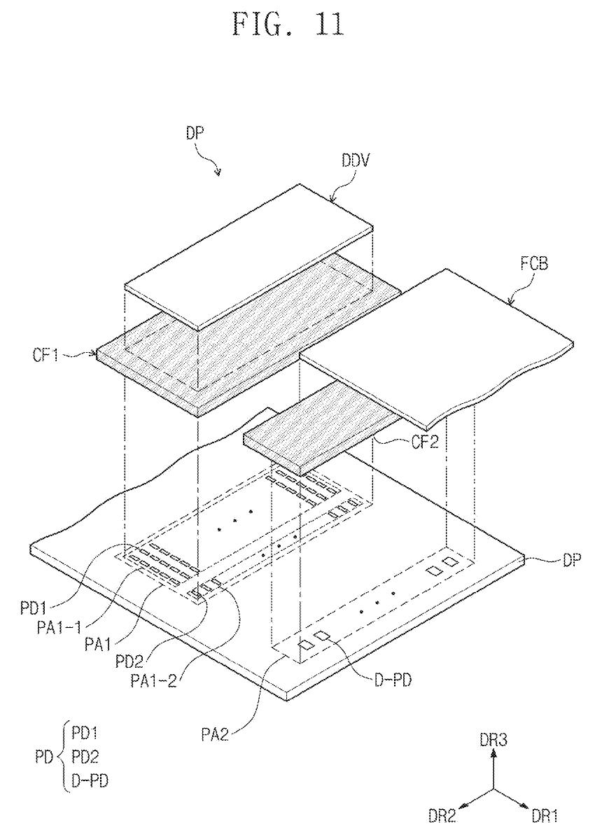

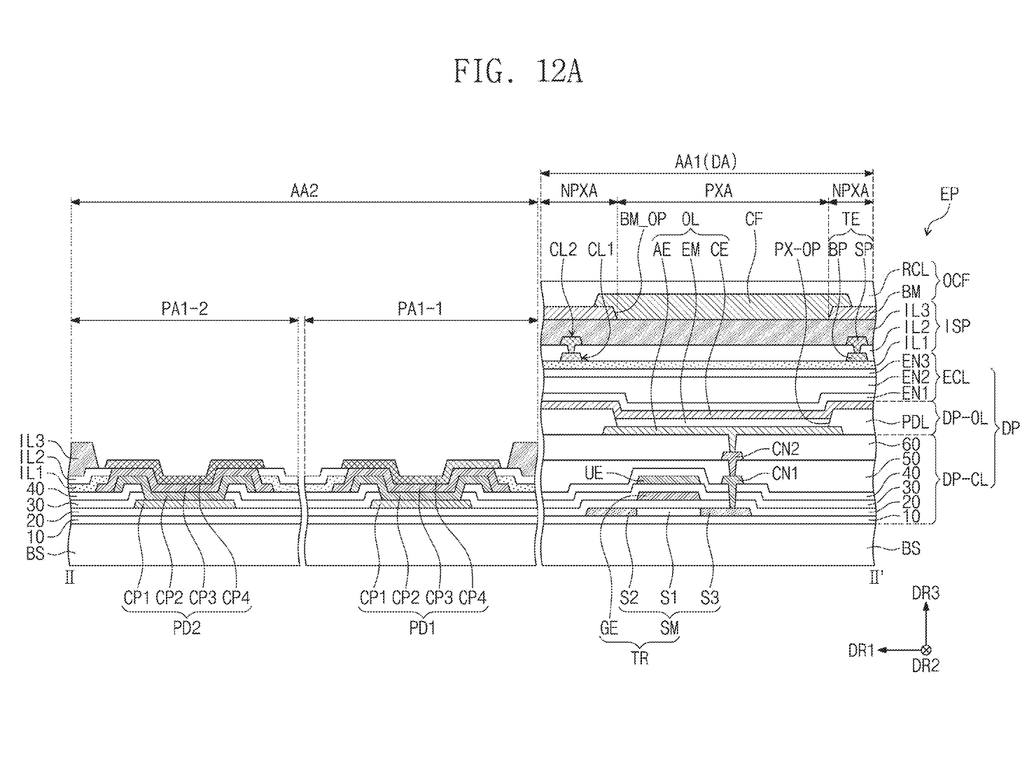

FIG. 11 is a perspective view illustrating a portion of the display panel illustrated in FIG. 7 according to one or more embodiments.

As an example, FIG. 11 briefly illustrates some components of the display panel DP arranged to correspond to the second non-bending portion AA2.

For example, the sensing pads I-PD illustrated in FIG. 8 are omitted in FIG. 11 for clarity.

For convenience of explanation, the display panel DP, the data driver DDV, and the flexible circuit board FCB are separated from each other.

Among the components illustrated in FIG. 11, descriptions of the same components as those described with reference to the above-mentioned drawings will not be provided or simplified.

The second non-bending portion AA2 corresponds to a partial region of the non-display region NDA (see FIG. 7). As illustrated in FIG. 11, in the non-display region NDA or the second non-bending portion AA2, a region to which the data driver DDV is bonded may be defined as a first pad region PA1, and a region to which the flexible circuit board FCB is bonded may be defined as a second pad region PA2.

The data driver DDV may be bonded to the first pad region PA1 through a first conductive adhesive layer CF1, and the flexible circuit board FCB may be bonded to the second pad region PA2 through a second conductive adhesive layer CF2. Each of the first conductive adhesive layer CF1 and the second conductive adhesive layer CF2 may be provided as an anisotropic conductive adhesive. For example, in one or more embodiments, each of the first conductive adhesive layer CF1 and the second conductive adhesive layer CF2 may include an adhesive resin and conductive particles dispersed in the adhesive resin.

Without being limited thereto, however, in one or more embodiments of the present disclosure, at least any one selected from among the first conductive adhesive layer CF1 and the second conductive adhesive layer CF2 may not be provided. For example, in one or more embodiments, the data driver DDV and the flexible circuit board FCB may be bonded to the first pad region PA1 and the second pad region PA2 by ultrasonic bonding, respectively.

The display panel DP may include a plurality of pads PD. The plurality of pads PD may include first signal pads PD1, second signal pads PD2, and display pads D-PD. The first signal pads PD1, the second signal pads PD2, and the display pads D-PD may be arranged in a signal transmission path.

The first signal pads PD1 may be arranged to correspond to output bumps of the data driver DDV and may be input pads that receive signals from the data driver DDV. The second signal pads PD2 may be arranged to correspond to input bumps of the data driver DDV and may be output pads that transmit signals to the data driver DDV. The display pads D-PD may be panel input pads that receive signals from the flexible circuit board FCB.

Each of the first signal pads PD1 may be electrically connected to the pixels PX (see FIG. 7) of the display panel DP through a signal line and transmit and receive signals to and from the pixels PX (see FIG. 7). Each of the second signal pads PD2 may be electrically connected to a corresponding display pad D-PD among the display pads D-PD through a signal line, and the display pads D-PD and the second signal pads PD2, which are electrically connected to each other, may be to transmit and receive signals to and from each other.

The first pad region PA1 may include a first sub-pad region PA1-1 and a second sub-pad region PA1-2. The first sub-pad region PA1-1 may be defined as a region in which the first signal pads PD1 are arranged. The second sub-pad region PA1-2 may be defined as a region in which the second signal pads PD2 are arranged.

The first signal pads PD1 may be arranged along the first direction DR1 and the second direction DR2 within the first sub-pad region PA1-1. Among the first signal pads PD1, those arranged along the first direction DR1 may be defined as a pad row. FIG. 11 illustrates an example in which five pad rows are arranged along the first direction DR1. The arrangement of the first signal pads PD1 is not limited to any one particular embodiment as long as at least two or more pad rows are arranged along the first direction DR1.

The second signal pads PD2 may be arranged along the second direction DR2 within the second sub-pad region PA1-2. In one or more embodiments, the second signal pads PD2 may be arranged in one pad row. However, the arrangement of the second signal pads PD2 is not limited thereto.

The flexible circuit board FCB may be arranged along the second direction DR2 on the display pads D-PD. For example, in one or more embodiments, the display pads D-PD may be arranged in one pad row. However, the arrangement of the display pads D-PD is not limited thereto.

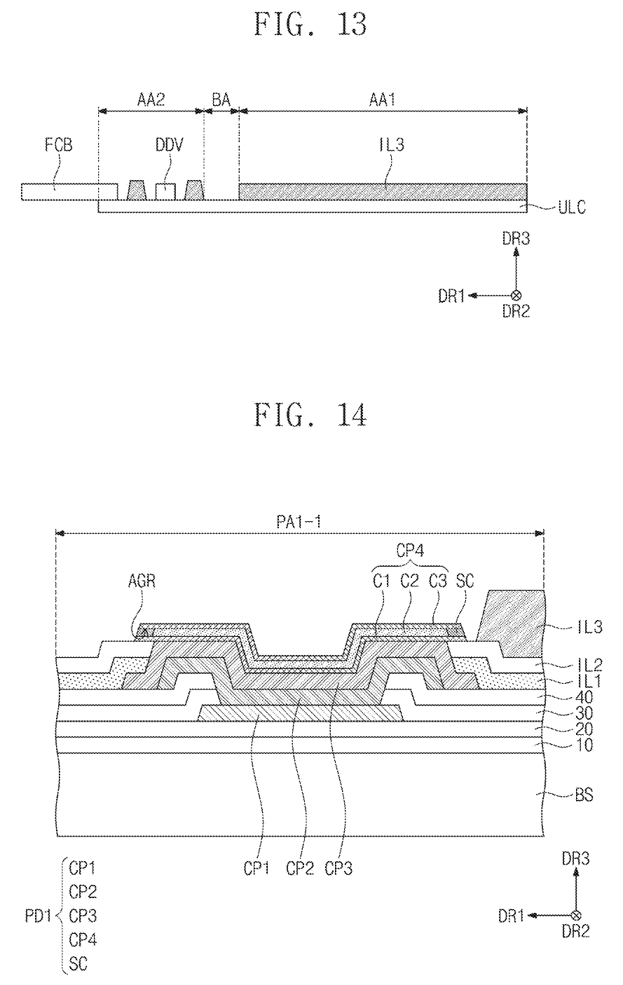

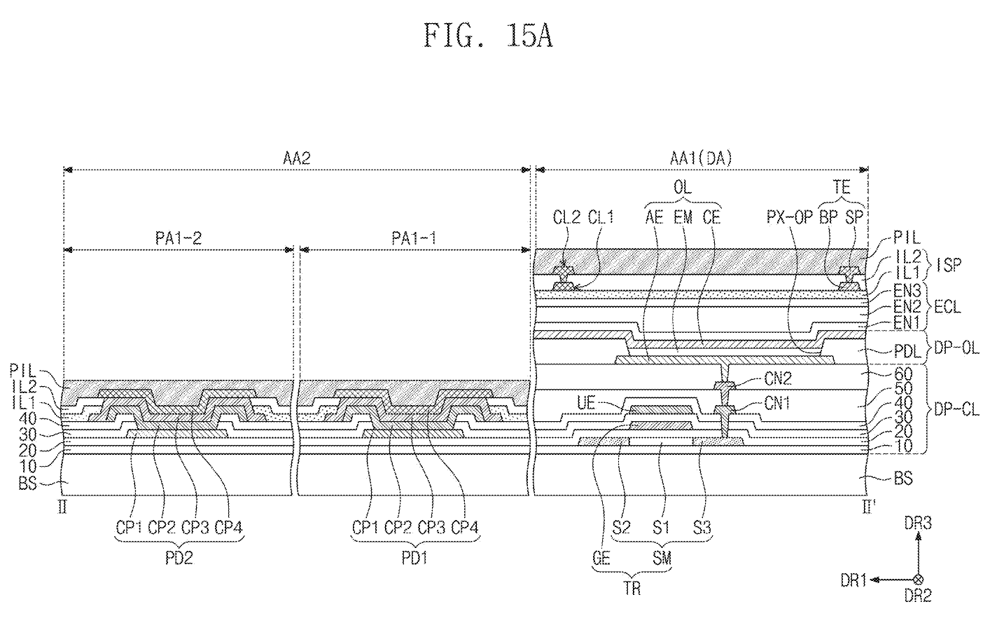

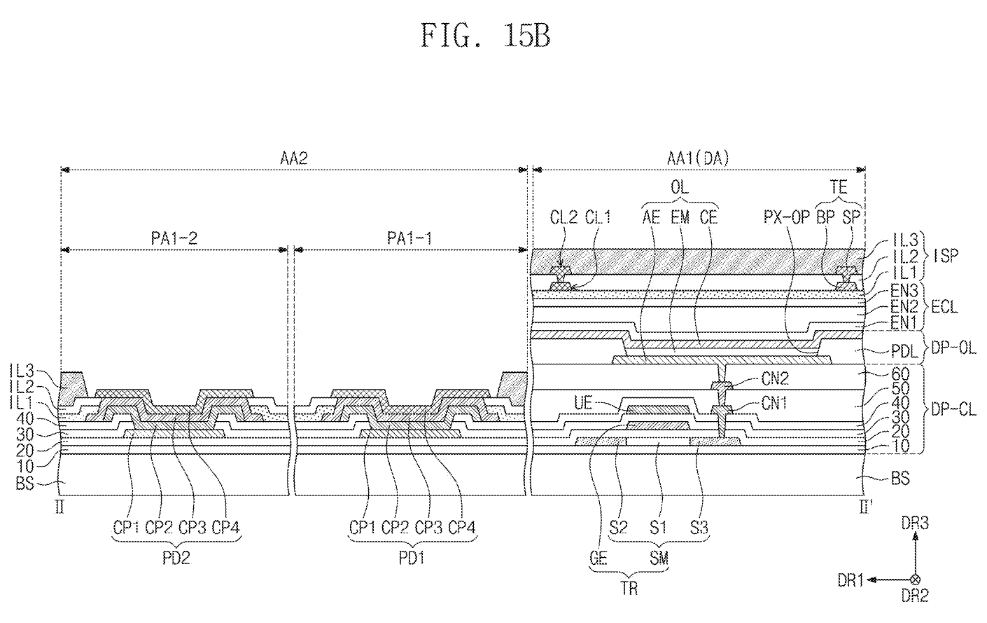

FIG. 12A is a cross-sectional view of the electronic panel corresponding to the line II-II' illustrated in FIG. 7 according to one or more embodiments. FIG. 12B is a cross-sectional view of the electronic panel corresponding to the line II-II' illustrated in FIG. 7 according to one or more embodiments. FIG. 12C is a cross-sectional view of the electronic panel corresponding to the line II-II' illustrated in FIG. 7 according to one or more embodiments. FIG. 13 is a cross-sectional view illustrating a portion of the electronic panel according to one or more embodiments. FIG. 14 is an enlarged cross-sectional view of the first signal pad PD1 illustrated in FIG. 12A according to one or more embodiments.

As example embodiments, FIGS. 12A to 12C each illustrate a cross section of the input sensing unit ISP and the anti-reflection layer OCF that correspond to the line II-II' of FIG. 7.

As example embodiments, FIGS. 12A to 12C each illustrate a cross-section of the pixel PX (see FIG. 7) arranged in the first non-bending portion AA1 and the first and second signal pads PD1 and PD2 arranged in the second non-bending portion AA2.

Among the components illustrated in FIGS. 12A to 14, descriptions of the same components as those described with reference to the above-mentioned drawings will not be provided or simplified.

Referring to FIG. 12A, the display panel DP may include a base substrate BS, a circuit layer DP-CL, a display element layer DP-OL, and an encapsulation layer ECL.

The base substrate BS may have insulating properties and provide a base surface on which components of the electronic panel EP are arranged. The base substrate BS may be flexible so as to be bendable. As described above, the base substrate BS may include a first non-bending portion AA1, a bending portion BA (see FIG. 7), and a second non-bending portion AA2, and the bending portion BA (see FIG. 7) of the base substrate BS may be bent at a set or predetermined curvature.

The circuit layer DP-CL may include insulating layers 10, 20, 30, 40, 50, and 60 (for convenience of description, also referred to insulating layers 10 to 60) each arranged on the base substrate BS, a transistor TR of the pixel PX (see FIG. 7), an upper electrode UE, and connection electrodes CN1 and CN2. The insulating layers 10 to 60 may include first to sixth insulating layers 10 to 60 sequentially stacked along the thickness direction on the base substrate BS. However, the embodiment of the insulating layers 10 to 60 included in the circuit layer DP-CL is not limited thereto and may be changed according to the configuration or manufacturing process of the circuit layer DP-CL.

The first insulating layer 10 may be arranged on (e.g., directly on) the base substrate BS. The first insulating layer 10 may be provided as a barrier layer and/or a buffer layer that prevents foreign substances from entering from the outside. The first insulating layer 10 may improve the bonding strength between the base substrate BS and a semiconductor pattern SM and/or a conductive pattern of the circuit layer DP-CL. The first insulating layer 10 may include at least any one of a silicon oxide layer or a silicon nitride layer. In one or more embodiments of the present disclosure, the first insulating layer 10 may include silicon oxide layers and silicon nitride layers that are alternately stacked.

The pixel PX (see FIG. 7) may be arranged on the base substrate BS. The pixel PX (see FIG. 7) may be arranged to correspond to the display region DA of the first non-bending portion AA1. The pixel PX (see FIG. 7) may include a transistor TR and a light-emitting element OL. The transistor TR may include a semiconductor pattern SM and a gate electrode GE. The semiconductor pattern SM may be arranged on the first insulating layer 10. The semiconductor pattern SM may include a channel S1, a source S2, and a drain S3. In one or more embodiments, the semiconductor pattern SM may include a silicon semiconductor, which may be a single-crystal silicon semiconductor, a polysilicon semiconductor, or an amorphous silicon semiconductor. Without being limited thereto, in one or more embodiments, the semiconductor pattern SM may include an oxide semiconductor. The semiconductor pattern SM according to one or more embodiments of the disclosure may be formed of one or more suitable materials as long as it has semiconductor properties, and the present disclosure is not limited to any one specific embodiment.

The semiconductor pattern SM may include a plurality of regions having different electrical properties depending on whether or not it has been doped or reduced. For example, the semiconductor pattern SM may include a highly conductive region formed as a result of doping or reduction of metal oxide, and the highly conductive region may serve as an electrode of the transistor TR or a signal line. This may correspond to the source S2 and the drain S3 of the transistor TR. The semiconductor pattern SM may include a relatively less conductive region because it has not been doped, and this may correspond to the channel S1 (or active) of the transistor TR.

The second insulating layer 20 may be arranged on the first insulating layer 10 and cover the semiconductor pattern SM. The gate electrode GE may be arranged on the second insulating layer 20. The second insulating layer 20 may be arranged between the semiconductor pattern SM and the gate electrode GE of the transistor TR. The gate electrode GE may overlap the channel S1 of the semiconductor pattern SM on a plane (e.g., in plan view). The gate electrode GE may function as a mask in the process of doping the semiconductor pattern SM. The gate electrode GE may include, but is not limited to, molybdenum (Mo), an alloy containing molybdenum, titanium (Ti), an alloy containing titanium, and/or the like, each of which has heat resistance.

The structure of the transistor TR illustrated in FIG. 12A is an example, and the source S2 and the drain S3 of the transistor TR may be electrodes formed independently from the semiconductor pattern SM. In this regard, the source S2 and the drain S3 may each be in contact with the semiconductor pattern SM, or may be connected to the semiconductor pattern SM by passing through an insulating layer. In addition, the gate electrode GE may be arranged to overlap the semiconductor pattern SM. The transistor TR according to one or more embodiments of the disclosure may be formed in one or more suitable structures and is not limited to any one particular embodiment. In addition, although not illustrated, the transistor TR may be provided in plurality. For example, in one or more embodiments, the pixel PX may include seven transistors TR and at least one capacitor.

In one or more embodiments, the second insulating layer 20 and the third to sixth insulating layers 30 to 60 which will be described later may include at least one of an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acrylic-based resin, a methacrylic-based resin, polyisoprene, a vinyl-based resin, an epoxy-based resin, a urethane-based resin, a cellulose-based resin, a siloxane-based resin, a polyamide-based resin, or a perylene-based resin.

The third insulating layer 30 may be arranged on the second insulating layer 20 and cover the gate electrode GE. The upper electrode UE may be arranged on the third insulating layer 30. The upper electrode UE may overlap the gate electrode GE on a plane (in plan view), and the gate electrode GE and the upper electrode UE that overlap each other may form a capacitor.

The fourth insulating layer 40 may be arranged on the third insulating layer 30 and cover the upper electrode UE. The connection electrodes CN1 and CN2 may include a first connection electrode CN1 and a second connection electrode CN2. The first connection electrode CN1 may be arranged on the fourth insulating layer 40. The fifth insulating layer 50 may be arranged on the fourth insulating layer 40 and cover the first connection electrode CN1. The second connection electrode CN2 may be arranged on the fifth insulating layer 50. The sixth insulating layer 60 may be arranged on the fifth insulating layer 50 and cover the second connection electrode CN2. In one or more embodiments of the present disclosure, at least any one of the fifth insulating layer 50 or the sixth insulating layer 60 may include an organic layer, cover a step difference between components arranged therebelow, and provide a flat upper surface.

The first connection electrode CN1 may be electrically connected to the drain S3 of the semiconductor pattern SM through a contact hole passing through the second to fourth insulating layers 20 to 40. The second connection electrode CN2 may be electrically connected to the first connection electrode CN1 through a contact hole passing through the fifth insulating layer 50.

Each of the first connection electrode CN1 and the second connection electrode CN2 may include a conductive material. Each of the first connection electrode CN1 and the second connection electrode CN2 may include gold, silver, copper, aluminum, platinum, molybdenum, titanium, or an alloy thereof. At least any one of the first connection electrode CN1 and/or the second connection electrode CN2 may have a multi-layer structure including conductive layers. For example, in one or more embodiments, at least any one of the first connection electrode CN1 and/or the second connection electrode CN2 may have a three-layer structure of titanium/aluminum/titanium. However, embodiments of the present disclosure are not limited thereto.

According to one or more embodiments of the circuit layer DP-CL, at least any one of the first connection electrode CN1 and/or the second connection electrode CN2 may not be provided. Alternatively, according to one or more embodiments of the circuit layer DP-CL, an additional connection electrode connecting the transistor TR and the light-emitting element OL to each other may be further arranged. Depending on the number of insulating layers arranged between the light-emitting element OL and the transistor TR, the electrical connection method between the light-emitting element OL and the transistor TR may be variously changed and is not limited to any one particular embodiment.

The display element layer DP-OL may include the light-emitting element OL and a pixel defining film PDL. The light-emitting element OL and the pixel defining film PDL may be arranged on the sixth insulating layer 60. The light-emitting element OL may include a first electrode AE, a light-emitting layer EM, and a second electrode CE.

The first electrode AE may be electrically connected to the second connection electrode CN2 through a contact hole passing through the sixth insulating layer 60. The first electrode AE may be electrically connected to the transistor TR through the first and second connection electrodes CN1 and CN2.

A pixel opening PX-OP, which exposes at least a portion of the first electrode AE, may be defined in the pixel defining film PDL. A (e.g., one) region of the first electrode AE exposed from the pixel defining film PDL may correspond to a light-emitting region PXA. The pixel defining film PDL may include an inorganic layer, an organic layer, or a composite material layer. According to one or more embodiments of the present disclosure, the pixel defining film PDL may further include a black pigment and/or a black dye.

The light-emitting layer EM may be arranged on the first electrode AE. The light-emitting layer EM may provide light of a set or predetermined color. The light-emitting layer EM may be arranged to correspond to the pixel opening PX-OP defined in the pixel defining film PDL. The light-emitting element OL and the pixel opening PX-OP may be provided in plurality, and the light-emitting layers EM of the light-emitting elements OL may be respectively arranged to correspond to the pixel openings PX-OP and provided in the form of patterns spaced and/or apart (e.g., spaced apart or separated) from each other. Without being limited thereto, however, in one or more embodiments, the light-emitting layers EM of the light-emitting elements OL may be formed as an integrated common layer.

The second electrode CE may be arranged on the light-emitting layer EM and the pixel defining film PDL. The second electrode CE may be provided as a common electrode commonly arranged in the pixels PX (see FIG. 7).

In one or more embodiments, the light-emitting element OL may further include at least any one of a hole control region arranged between the first electrode AE and the light-emitting layer EM and/or an electron control region arranged between the light-emitting layer EM and the second electrode CE. The hole control region may include at least one of a hole generation layer, a hole transport layer, or an electron blocking layer, and the electron control region may include at least one of an electron generation layer, an electron transport layer, or a hole blocking layer.

The display region DA may include a light-emitting region PXA and a non-light-emitting region NPXA adjacent to the light-emitting region PXA. The light-emitting region PXA may overlap the light-emitting element OL. In one or more embodiments, a portion of the first electrode AE exposed by the light-emitting opening PX-OP may correspond to the light-emitting region PXA. A region in which the pixel defining film PDL is arranged may correspond to the non-light-emitting region NPXA around (e.g., surrounding) the light-emitting region PXA.

The encapsulation layer ECL may be arranged on the display element layer DP-OL. The encapsulation layer ECL may be arranged on the light-emitting element OL and the pixel defining film PDL to seal the light-emitting element OL. The encapsulation layer ECL may include at least one of an inorganic film or an organic film. In one or more embodiments, the encapsulation layer ECL may include a first inorganic film EN1, a second inorganic film EN3, and an organic film EN2 arranged between the first and second inorganic films EN1 and EN3. However, the configuration of the encapsulation layer ECL is not limited thereto as long as it can seal the light-emitting element OL.

The first inorganic film EN1 may be arranged on the second electrode CE, and the organic film EN2 and the second inorganic film EN3 may be sequentially arranged on the first inorganic film EN1 in the thickness direction of the display panel DP. The first and second inorganic films EN1 and EN3 may protect the light-emitting element OL from moisture and/or oxygen entering from the outside. For example, each of the first and second inorganic films EN1 and EN3 may include at least one of silicon nitride, silicon oxynitride, silicon oxide, titanium oxide, or aluminum oxide.

However, the materials of the first and second inorganic films EN1 and EN3 are not limited to the above examples. The organic film EN2 may prevent or reduce foreign substances from entering the light-emitting element OL and cover the step difference of the components arranged below the organic film EN2. For example, the organic film EN2 may include an acrylic-based organic material. However, the material of the organic film EN2 is not limited to the above example.

The input sensing unit ISP may be arranged on the display panel DP. The input sensing unit ISP may include a base layer IL1, a first sensing insulating layer IL2, a first sensing conductive layer CL1, a second sensing conductive layer CL2, and a second sensing insulating layer IL3. The descriptions provided above may be equally applied to each component.

The base layer IL1 may be in contact with an uppermost layer of the encapsulation layer ECL. For example, the base layer IL1 may be in contact with the second inorganic film EN3 of the encapsulation layer ECL. The base layer IL1 of the input sensing unit ISP may be formed directly on a base surface provided by the encapsulation layer ECL. Without being limited thereto, however, according to one or more embodiments of the disclosure, the base layer IL1 may not be provided, and in these embodiments, the first sensing conductive layer CL1 of the input sensing unit ISP may be in contact with the encapsulation layer ECL.

The first sensing conductive layer CL1 may be arranged on the base layer IL1, and the second sensing conductive layer CL2 may be arranged on the first sensing insulating layer IL2. The first sensing conductive layer CL1 and the second sensing conductive layer CL2 may form a sensing electrode TE. The sensing electrode TE may correspond to any one of the first and second sensing electrodes TEX and TEY (see FIG. 8) described above. For example, in one or more embodiments, the first sensing conductive layer CL1 may include a connection pattern BP of the sensing electrode TE, and the second sensing conductive layer CL2 may include a sensing pattern SP of the sensing electrode TE. Without being limited thereto, however, the first sensing conductive layer CL1 may include a sensing pattern SP, and the second sensing conductive layer CL2 may include a connecting pattern BP.

The connection pattern BP may correspond to the first connection pattern BP1 (see FIG. 8) or the second connection pattern BP2 (see FIG. 8) described above, and the sensing pattern SP may correspond to the first sensing pattern SP1 (see FIG. 8) or the second sensing pattern SP2 (see FIG. 8) described above. The connection pattern BP may be arranged in a layer different from that of the sensing pattern SP and connected thereto through contact holes passing through the first sensing insulating layer IL2. Without being limited thereto, however, in one or more embodiments, the connection pattern BP and the sensing pattern SP may be arranged in a same layer and formed integrally.

The sensing electrode TE may be a mesh-shaped pattern and may be arranged to correspond to a region in which the pixel defining film PDL is arranged. Without being limited thereto, however, in one or more embodiments, the sensing electrode TE may be provided as a single-shaped pattern overlapping the light-emitting element OL, and in these embodiments, the sensing electrode TE may include a transparent conductive material.

The second sensing insulating layer IL3 may include an organic material. The second sensing insulating layer IL3 may be arranged on the second conductive layer CL2. The second sensing insulating layer IL3 may be arranged on the first sensing insulating layer IL2. The second sensing insulating layer IL3 may cover the sensing pattern SP.

Referring to FIGS. 10B and 12A, if (e.g., when) the second sensing insulating layer IL3 includes an inorganic material, a tensile stress may be applied to the input sensing unit ISP arranged in the first reverse curvature portion ICV1 and the second reverse curvature portion ICV2. A tensile stress may be applied to the second sensing insulating layer IL3 arranged in the first reverse curvature portion ICV1 and the second reverse curvature portion ICV2. Accordingly, a crack may occur in the second sensing insulating layer IL3. The crack may propagate to the encapsulation layer ECL. The crack that has propagated to the encapsulation layer ECL may further propagate to the display element layer DP-OL or the circuit layer DP-CL. As a result, a defect may occur in the display device DD.

However, the second sensing insulating layer IL3 according to one or more embodiments of the disclosure may include an organic material. When the display device DD is folded, a crack may be prevented from occurring in the second sensing insulating layer IL3. Accordingly, it may prevent a crack from propagating to the display element layer DP-OL or the circuit layer DP-CL. As a result, a defect in the display device DD may be prevented. For example, to prevent or block cracks and defects in the display device during folding, the second sensing insulating layer is formed of an organic material rather than an inorganic material, thereby reducing tensile stress and inhibiting crack propagation to underlying layers such as the encapsulation, display element, and/or circuit layers.

A thickness of the second sensing insulating layer IL3 may be greater than a thickness of a portion of the sensing pattern SP arranged on an upper surface of the first sensing insulating layer IL2. For example, the thickness of the second sensing insulating layer IL3 may be about 3.4 to 3.8 times greater than the thickness of the sensing pattern SP. In one or more embodiments, the thickness of the second sensing insulating layer IL3 may be about 3.6 times greater than the thickness of the sensing pattern SP. The thickness of the second sensing insulating layer IL3 may be defined as a length in the third direction DR3 from the upper surface of the first sensing insulating layer IL2 to an upper surface of the second sensing insulating layer IL3. The thickness of a portion of the sensing pattern SP arranged on the upper surface of the first sensing insulating layer IL2 may be defined as a length in the third direction DR3 from a lower surface of the sensing pattern SP, which is in contact with the upper surface of the first sensing insulating layer IL2, to an upper surface of the sensing pattern SP.

Referring to FIGS. 12A and 13, as an example, in FIG. 13, the display panel DP and the input sensing unit ISP excluding the second sensing insulating layer IL3 are each simply illustrated as one layer. In addition, the anti-reflection layer OCF is omitted in FIG. 13. Hereinafter, the display panel DP and the input sensing unit ISP excluding the second sensing insulating layer IL3 may be defined as or referred to a lower member ULC.

The second sensing insulating layer IL3 may be arranged in the first non-bending portion AA1 and the second non-bending portion AA2. In the second non-bending portion AA2, the second sensing insulating layer IL3 may be arranged on the upper surface of the first sensing insulating layer IL2.

The second sensing insulating layer IL3 may not be arranged in the bending portion BA. The second sensing insulating layer IL3 may not overlap the bending portion BA. Accordingly, a thickness of the bending portion BA is reduced, so that the bending portion BA can be easily bent.

The second sensing insulating layer IL3 may be arranged in the second non-bending portion AA2. The second sensing insulating layer IL3 may not overlap the pads PD1 and PD2. The second sensing insulating layer IL3 may not overlap the data driver DDV. The second sensing insulating layer IL3 may be spaced and/or apart (e.g., spaced apart or separated) from the data driver DDV in the second non-bending portion AA2.

The second sensing insulating layer IL3 may be spaced and/or apart (spaced apart or separated) from the flexible circuit board FCB in the second non-bending portion AA2. The second sensing insulating layer IL3 may not overlap the flexible circuit board FCB.

The anti-reflection layer OCF may be arranged on the input sensing unit ISP. The anti-reflection layer OCF may be arranged on a flat upper surface provided by the second sensing insulating layer IL3. The anti-reflection layer OCF may include a color filter CF, a light-shielding pattern BM, and an overcoating layer RCL. In FIG. 12A, a plurality of light-shielding patterns BM are illustrated, but substantially, the light-shielding patterns BM may be formed integrally.

The light-shielding pattern BM may be arranged on the input sensing unit ISP. The light-shielding pattern BM is a layer having a black color, and in one or more embodiments of the present disclosure, the light-shielding pattern BM may include a black coloring agent. The black coloring agent may include a black dye and/or a black pigment. The black coloring agent may include carbon black, a metal such as chromium, or an oxide thereof. However, this is merely an example, and the material constituting the light-shielding pattern BM is not particularly limited thereto as long as it is a material that absorbs light.

The light-shielding pattern BM may prevent or reduce external light reflection by the first conductive layer CL1 and the second conductive layer CL2. The light-shielding pattern BM may be arranged to overlap the pixel defining film PDL. The light-shielding pattern BM may be arranged in the non-light-emitting region NPXA. A light-shielding opening BM_OP may be defined in the light-shielding pattern BM. The light-shielding opening BM_OP may overlap the pixel opening PX-OP.

The color filter CF may be arranged on the input sensing unit ISP. The color filter CF may be arranged in the light-shielding opening BM_OP defined by the light-shielding pattern BM. A portion of the color filter CF may be arranged on the light-shielding pattern BM.

The color filter CF may overlap the light-emitting element OL. The color filter CF may be to transmit light having a specific wavelength range, which is generated by the light-emitting element OL, and absorb most of light having a wavelength range outside the specific wavelength range.

Although one color filter CF is illustrated in FIG. 12A, embodiments of the disclosure are not limited thereto, and the color filter CF may be provided in plurality.

Each of the color filters CF may overlap a corresponding light-emitting element OL among the plurality of light-emitting elements OL. Each of the color filters CF may be to transmit light having a different wavelength range. The overcoating layer RCL may cover the light-shielding pattern BM and the color filter CF. The overcoating layer RCL may include an organic material and provide a flat upper surface.

Referring to FIG. 12B, an anti-reflection layer OCFa may include a color filter CFa and an overcoating layer RCL. The anti-reflection layer OCFa may not include (e.g., may exclude) the light-shielding pattern BM of FIG. 12A.

The color filter CFa may include a first color filter CF1, a second color filter CF2, and a third color filter CF3. Each of the first to third color filters CF1, CF2, and CF3 may be to transmit light having a specific wavelength range and absorb most of the light having a wavelength range outside the specific wavelength range.

For example, the first color filter CF1 may include a red color filter. The second color filter CF2 may include a green color filter. The third color filter CF3 may include a blue color filter. The red color filter may be to transmit red light and absorb most of green light and blue light. The green color filter may be to transmit green light and absorb most of red light and blue light. The blue color filter may be to transmit blue light and absorb most of red light and green light.

At least two or more selected from among the first to third color filters CF1, CF2, and CF3 may overlap each other within the non-light-emitting region NPXA. For example, in one or more embodiments, the first to third color filters CF1, CF2, and CF3 may be arranged to overlap one another along the third direction DR3 within the non-light-emitting region NPXA. For example, in one or more embodiments, the first color filter CF1 may be arranged below the third color filter CF3, and the second color filter CF2 may be arranged below the first color filter CF1.

Referring to FIG. 12C, the electronic panel EP according to this embodiment may not include (e.g., may exclude) the anti-reflection layer OCF (see FIG. 12A).

Referring to FIGS. 12A to 12C in conjunction with FIG. 11, on the base substrate BS, the first insulating layer 10 and the second insulating layer 20 may extend from the first non-bending portion AA1 and be arranged in the second non-bending portion AA2. The first signal pad PD1 and the second signal pad PD2 may be arranged on the second insulating layer 20. The first signal pad PD1 may be arranged in the first sub-pad region PA1-1, and the second signal pad PD2 may be arranged in the second sub-pad region PA1-2. The first signal pad PD1 may be arranged to be closer to the display region DA within the first non-bending portion AA1 than the second signal pad PD2.

Each of the first and second signal pads PD1 and PD2 may include a plurality of conductive patterns CP1, CP2, CP3, and CP4 arranged along the thickness direction. The first conductive patterns CP1 of the first signal pad PD1 and the second signal pad PD2 may be arranged on the second insulating layer 20.

The first conductive patterns CP1 of the first signal pad PD1 and the second signal pad PD2 may be formed through the same process as the gate electrode GE of the transistor TR. For example, a conductive layer may be formed on the second insulating layer 20 through a deposition process such as sputtering or chemical vapor deposition, and then the conductive layer may be patterned to form the first conductive patterns CP1 of the first and second signal pads PD1 and PD2 and the gate electrode GE. The first conductive patterns CP1 of the first and second signal pads PD1 and PD2 may be arranged in a same layer as the gate electrode GE of the transistor TR and may include a same material as the gate electrode GE.

The third insulating layer 30 and the fourth insulating layer 40 may extend from the first non-bending portion AA1 and be arranged in the second non-bending portion AA2. Through holes that expose upper surfaces of the first conductive patterns CP1 of the first signal pad PD1 and the second signal pad PD2 may be defined in the third insulating layer 30 and the fourth insulating layer 40. The third insulating layer 30 and the fourth insulating layer 40 may be formed by sequentially depositing insulating layers on the first non-bending portion AA1 and the second non-bending portion AA2 and then etching portions of the upper surfaces of the first conductive patterns CP1 of the first and second signal pads PD1 and PD2.

As illustrated in FIG. 12A, at least some of the insulating layers arranged in the first non-bending portion AA1 may be arranged in the second non-bending portion AA2, and the stacking structure of the insulating layers arranged in the second non-bending portion AA2 is not particularly limited to what is illustrated.

The second conductive patterns CP2 of the first signal pad PD1 and the second signal pad PD2 may be arranged on the upper surfaces of the exposed first conductive patterns CP1, respectively. The second conductive patterns CP2 may be in contact with the first conductive patterns CP1, respectively. Portions of the second conductive patterns CP2 may be arranged on the fourth insulating layer 40. For example, portions of the second conductive patterns CP2 may cover inner side surfaces of the third and fourth insulating layers 30 and 40 exposed by a through hole and may be arranged on the fourth insulating layer 40.

The second conductive patterns CP2 of the first signal pad PD1 and the second signal pad PD2 may be formed through a same process as any one of the conductive electrodes in the circuit layer DP-CL. For example, the second conductive patterns CP2 of the first signal pad PD1 and the second signal pad PD2 may be formed through a same process as the first connection electrode CN1. A conductive layer may be formed on the fourth insulating layer 40 through a deposition process such as sputtering or chemical vapor deposition, and then the conductive layer may be patterned to form the second conductive patterns CP2 of the first and second signal pads PD1 and PD2 and the first connection electrode CN1. The second conductive patterns CP2 of the first and second signal pads PD1 and PD2 may be arranged in a same layer as the first connection electrode CN1 and may include a same material as the first connection electrode CN1.

The third conductive patterns CP3 of the first signal pad PD1 and the second signal pad PD2 may be respectively arranged on the second conductive patterns CP2. The third conductive patterns CP3 may be in contact with the second conductive patterns CP2, respectively.

The third conductive patterns CP3 of the first signal pad PD1 and the second signal pad PD2 may be formed through a same process as any one of the conductive electrodes in the circuit layer DP-CL. For example, the third conductive patterns CP3 of the first signal pad PD1 and the second signal pad PD2 may be formed through a same process as the second connection electrode CN2. The fifth insulating layer 50 arranged below the second connection electrode CN2 may be opened to correspond to a region in which the first and second signal pads PD1 and PD2 are arranged. For example, the fifth insulating layer 50 may not be arranged on the second conductive patterns CP2 of the first and second signal pads PD1 and PD2, and a portion of a conductive layer deposited on the fifth insulating layer 50 may be in contact with the second conductive patterns CP2. After forming a conductive layer on the fifth insulating layer 50 through a deposition process such as sputtering or chemical vapor deposition, the conductive layer may be patterned to form the third conductive patterns CP3 of the first and second signal pads PD1 and PD2 and the second connection electrode CN2. The third conductive patterns CP3 may be arranged in a same layer as the second connection electrode CN2 and may include a same material as the second connection electrode CN2.

On the base substrate BS, the base layer IL1 may extend from the first non-bending portion AA1 and be arranged in the second non-bending portion AA2. The base layer IL1 may cover edges of the third conductive patterns CP3 of the first signal pad PD1 and the second signal pad PD2.

On the base substrate BS, the first sensing insulating layer IL2 may extend from the first non-bending portion AA1 and be arranged in the second non-bending portion AA2. The first sensing insulating layer IL2 may be arranged on the base layer IL1. The first sensing insulating layer IL2 may overlap the edges of the third conductive patterns CP3 of the first signal pad PD1 and the second signal pad PD2.

The fourth conductive patterns CP4 of the first signal pad PD1 and the second signal pad PD2 may be arranged on upper surfaces of the third conductive patterns CP3. The fourth conductive patterns CP4 may be in contact with the third conductive patterns CP3. Portions of the fourth conductive patterns CP4 may be arranged on the first sensing insulating layer IL2.

The fourth conductive patterns CP4 may be formed through a same process as any one of the conductive electrodes in the input sensing unit ISP. For example, the fourth conductive patterns CP4 may be formed through a same process as the second sensing conductive layer CL2.

Referring to FIG. 14, the fourth conductive pattern CP4 may include a plurality of conductive layers C1, C2, and C3 sequentially stacked in the third direction DR3. Although the structure of the fourth conductive pattern CP4 of the first signal pad PD1 is illustrated as an example in FIG. 14, the description thereof may be equally applied to the fourth conductive pattern CP4 of the second signal pad PD2. The fourth conductive pattern CP4 may have a same stacked structure as the second sensing conductive layer CL2.

The plurality of conductive layers C1, C2, and C3 may include first to third conductive layers C1, C2, and C3. The first to third conductive layers C1, C2, and C3 may be sequentially stacked in the third direction DR3. The second conductive layer C2 may be arranged on an upper surface of the first conductive layer C1, and the third conductive layer C3 may be arranged on an upper surface of the second conductive layer C2. The second conductive layer C2 may be arranged between the first conductive layer C1 and the third conductive layer C3.

When viewed from the second direction DR2, both sides (e.g., two opposite sides) of the second conductive layer C2 opposite to each other in the first direction DR1 may be arranged further inward than both sides (e.g., two opposite sides) of the first conductive layer C1 and both sides (e.g., two opposite sides) of the third conductive layer C3. Accordingly, accommodating grooves AGR may be defined by the upper surface of the first conductive layer C1, a lower surface of the third conductive layer C3, and both sides (e.g., two opposite sides) of the second conductive layer C2. For example, an accommodating groove AGR may be defined by the upper surface of the first conductive layer C1, the lower surface of the third conductive layer C3, and a side (one of the both sides) of the second conductive layer C2. Here, for example, “further inward” refers to a position closer to the center of the pad structure along the first direction DR1, such that the lateral edges of the second conductive layer are recessed relative to the outer edges of the first and third conductive layers.

The first conductive layer C1 may include a material different from that of the second conductive layer C2. The first conductive layer C1 may include a same material as the third conductive layer C3. However, embodiments of the present disclosure are not necessarily limited thereto.

Each of the first conductive layer C1 and the third conductive layer C3 may include a metallic material having corrosion resistance. Because the first conductive layer C1 and the third conductive layer C3 are respectively arranged on the lower surface and upper surface of the second conductive layer C2, it may protect the second conductive layer C2 from scratches occurring during a process. In addition, the first conductive layer C1 and the third conductive layer C3 may prevent or reduce the second conductive layer C2 from being corroded due to moisture permeation. For example, in one or more embodiments, the first conductive layer C1 and the third conductive layer C3 may include at least one of molybdenum, titanium, or an alloy thereof. However, the materials of the first conductive layer C1 and the third conductive layer C3 are not limited to the above examples.

The second conductive layer C2 may be arranged between the first conductive layer C1 and the third conductive layer C3. The second conductive layer C2 may include a metallic material having low resistance. For example, in one or more embodiments, the second conductive layer C2 may include at least one of gold, silver, copper, aluminum, platinum, or an alloy thereof. However, the material of the second conductive layer C2 is not limited to the above examples.

The second conductive layer C2 may have a larger thickness than each of the first conductive layer C1 and the third conductive layer C3. Because the second conductive layer C2 including a relatively low-resistance material has a large thickness, the first signal pad PD1 may have a low resistance.

The first pad PD1 may include a plurality of dummy insulating patterns SC. The dummy insulating patterns SC may include an inorganic material. The dummy insulating patterns SC may be arranged in the accommodating grooves AGR. The dummy insulating patterns SC may be arranged on both sides (e.g., two opposite sides) of the second conductive layer C2 opposite to each other in the first direction DR1. The dummy insulating patterns SC may cover both sides (e.g., two opposite sides) of the second conductive layer C2. The two sides of the second conductive layer C2 may not be exposed to the outside by the dummy insulating patterns SC. In one or more embodiments, the second pad PD2 may also include the dummy insulating patterns SC.

The dummy insulating patterns SC may be arranged between the first conductive layer C1 and the third conductive layer C3. Among both sides (e.g., two opposite sides) of the dummy insulating patterns SC opposite to each other in the first direction DR1, one sides thereof spaced from the second conductive layer C2 may be aligned with both ends of the first conductive layer C1 and both ends of the third conductive layer C3. For example, the one sides of the dummy insulating patterns SC may have a same inclination angle as both ends of the first conductive layer C1 and both ends of the third conductive layer C3. However, this is merely an example, and both sides (e.g., two opposite sides) of the dummy insulating patterns SC opposite to each other in the first direction DR1 may be arranged further inward than both ends of the first conductive layer C1 and both ends of the third conductive layer C3. Here, for example, “further inward” refers to a position closer to the center of the pad structure along the first direction DR1, such that the lateral edges of the dummy insulating patterns are located within the outer boundaries defined by the first and third conductive layers.

Because the dummy insulating patterns SC cover both sides (e.g., two opposite sides) of the second conductive layer C2, the second conductive layer C2 may be prevented or reduced from being corroded. Accordingly, defects in the electronic panel EP may be prevented or reduced.

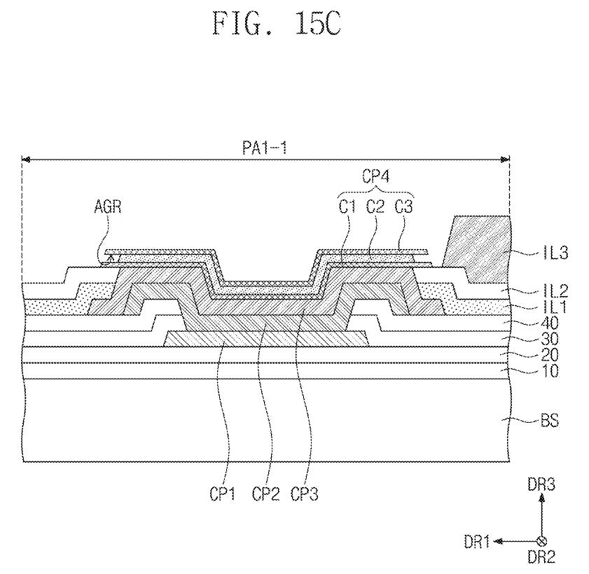

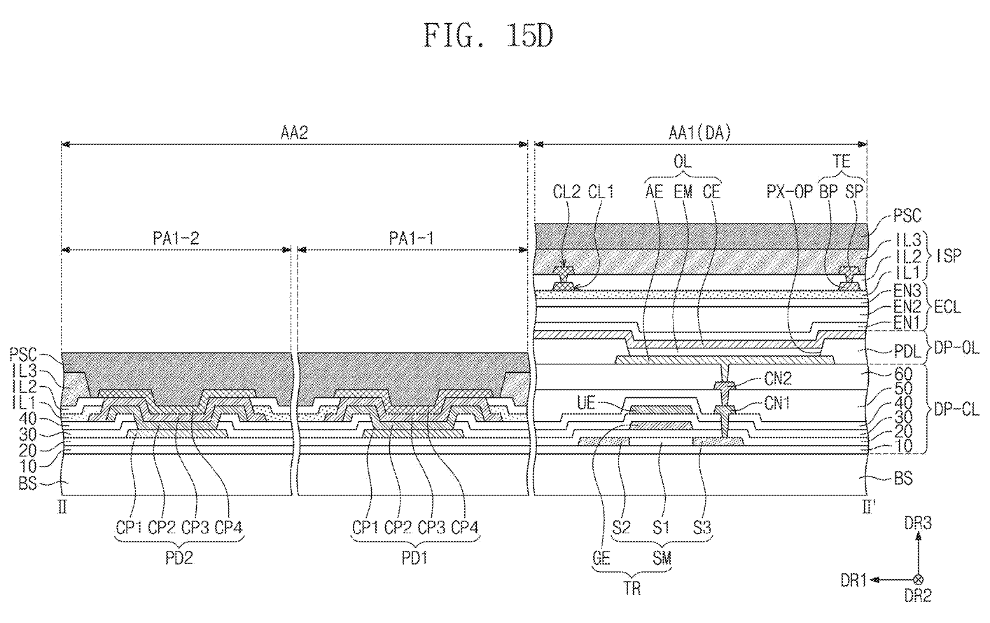

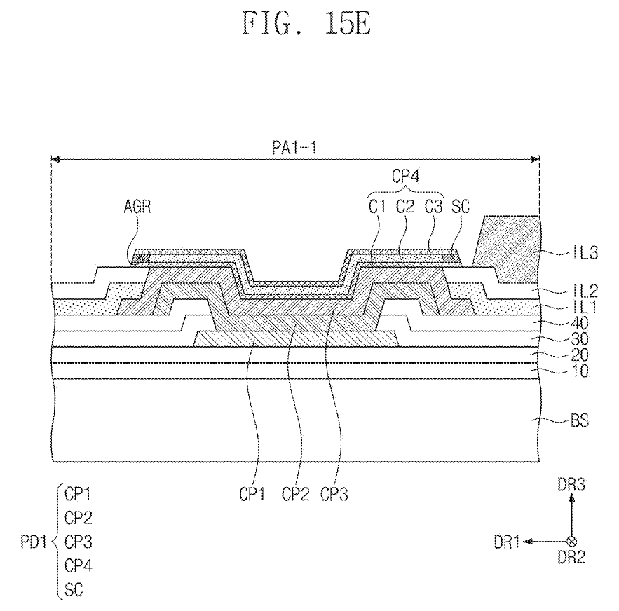

FIGS. 15A to 15E are cross-sectional views for explaining a method for manufacturing the second sensing insulating layer illustrated in FIG. 12A and a method for manufacturing the dummy insulating pattern illustrated in FIG. 14 according to one or more embodiments.

As example embodiments, FIGS. 15A to 15E illustrate a cross section of the display panel DP and a cross section of the input sensing unit ISP that correspond to the line II‒II' illustrated in FIG. 7.

As an example, FIGS. 15A to 15E illustrate cross-sections of the pixels PX (see FIG. 7) arranged in the first non-bending portion AA1 and the first and second signal pads PD1 and PD2 arranged in the second non-bending portion AA2.

Among the components illustrated in FIGS. 15A to 15E, descriptions of the same components as those described with reference to the above-mentioned drawings will not be provided or simplified.

Referring to FIG. 15A, the method for manufacturing the second sensing insulating layer IL3 (see FIG. 12A) may include providing an organic material on the first non-bending portion AA1 and the second non-bending portion AA2 to form a preliminary sensing insulating layer PIL. Although not illustrated, the organic material may also be provided on the bending portion BA, so that the preliminary sensing insulating layer PIL may also be formed on the bending portion BA. The preliminary sensing insulating layer PIL may be provided on the second sensing conductive layer CL2, the first sensing insulating layer IL2, and the conductive patterns CP1, CP2, CP3, and CP4 of the first pad PD1 and the second pad PD2.

Referring to FIGS. 15A to 15C, after the forming of the preliminary sensing insulating layer PIL, etching a portion of the preliminary sensing insulating layer PIL overlapping the pads PD1 and PD2 may be performed to form the second sensing insulating layer IL3. Although not illustrated, a portion of the preliminary sensing insulating layer PIL overlapping the second pad region PA2 connected to the bending portion BA and the flexible circuit board FCB (see FIG. 11) may also be etched. For example, the preliminary sensing insulating layer PIL may be etched using an etching solution after an exposure process. When the preliminary sensing insulating layer PIL is etched, the second sensing insulating layer IL3 may be formed.

As illustrated in FIG. 15C, when the preliminary sensing insulating layer PIL is etched, a portion of the fourth conductive pattern CP4 may be etched by an etching solution. The etching solution may flow to the fourth conductive pattern CP4. The second conductive layer C2 exposed to the outside from the first and third conductive layers C1 and C3 may be etched. Both sides of the second conductive layer C2 opposite to each other in the first direction DR1 may be etched. Accordingly, when the preliminary sensing insulating layer PIL is etched, accommodating grooves AGR may be defined. Although only the first pad PD1 is illustrated in FIG. 15C, without being limited thereto, the accommodating grooves AGR may also be defined in the second pad PD2.

Referring to FIG. 15D, after the forming of the second sensing insulating layer IL3, providing an inorganic material to the first non-bending portion AA1 and the second non-bending portion AA2 may be performed to form a preliminary insulating layer PSC. The preliminary insulating layer PSC may be formed on the pads PD1 and PD2 and the input sensing unit ISP. Although not illustrated, the inorganic material may also be provided to the bending portion BA (see FIG. 7).

Referring to FIGS. 12A and 15E, after the providing of the preliminary insulating layer PSC (see FIG. 15D), the preliminary insulating layer PSC (see FIG. 15D) may be etched. The preliminary insulating layer PSC arranged on the first non-bending portion AA1, the bending portion BA (see FIG. 7), and the second non-bending portion AA2 may be etched. For example, all of the preliminary insulating layers PSC arranged on the first non-bending portion AA1, the bending portion BA (see FIG. 7), and the second non-bending portion AA2 may be etched without a separate mask. Accordingly, the process may be simplified. After the etching of the preliminary insulating layer PSC, the dummy insulating patterns SC may be formed in the accommodating groove AGR.

In addition, because the dummy insulating patterns SC cover both sides (e.g., two opposite sides) of the second conductive layer C2, corrosion of the second conductive layer C2 may be prevented when the anti-reflection layer OCF is formed. Accordingly, defects in the electronic panel EP may be prevented or reduced.

According to one or more embodiments of the present disclosure, the input sensing unit may include an insulating layer including an organic material. Accordingly, although tensile stress is applied to the input sensing unit if (e.g., when) the electronic device is folded, cracks may be prevented from occurring in the input sensing unit.

According to one or more embodiments of the present disclosure, dummy insulating patterns may be arranged on both sides (e.g., two opposite sides) of at least any one of the conductive patterns of a pad. Accordingly, corrosion of the conductive pattern may be reduced or prevented.

According to one or more embodiments of the present disclosure, dummy insulating patterns may be disposed on both sides of at least one conductive pattern of a pad, and the input sensing unit may include an insulating layer formed of an organic material. This dual-structure approach—combining organic insulating layers with strategically placed dummy insulating patterns—enhances the mechanical and environmental reliability of the electronic device with the display panel. Specifically, the organic insulating layer mitigates the risk of crack formation under tensile stress during folding, while the dummy insulating patterns shield the exposed conductive layers from corrosive agents during subsequent processing steps, such as anti-reflection layer deposition. As a result, the likelihood of defects propagating to critical layers such as the display element layer and/or circuit layer may be significantly reduced, thereby improving the durability, performance, and/or lifespan of the electronic device with the display panel.

In the context of the present application and unless otherwise defined, the terms "use," "using," and "used" may be considered synonymous with the terms "utilize," "utilizing," and "utilized," respectively.

As utilized herein, the terms “substantially,” “about,” "approximately," or similar terms are used as terms of approximation and not as terms of degree, and are intended to account for the inherent deviations in measured or calculated values that would be recognized by those of ordinary skill in the art. “About” or "approximately" as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or "approximately" may mean within one or more standard deviations, or within ± 30%, ± 20%, ± 10%, or ± 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

The light emitting element, the display module, the display device, the electronic device, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although the above has been described with reference to one or more example embodiments of the present disclosure, those skilled in the art or those of ordinary skill in the art will understand that one or more suitable modifications and changes may be made to the disclosure within the scope that does not depart from the spirit and technical field of the disclosure described in the appended claims.

Accordingly, the technical scope of the disclosure should not be limited to the content described in the detailed description of the disclosure, but should be determined by the appended claims and equivalents thereof.

What is claimed is:

1. An electronic device, comprising:
a display panel comprising a first non-bending portion, a bending portion, and a second non-bending portion arranged in a first direction, the display panel further comprising a plurality of pads arranged in the second non-bending portion;
an input sensing unit on the display panel; and
an anti-reflection layer on the input sensing unit,
wherein the plurality of pads comprise:
a plurality of conductive patterns stacked in a thickness direction of the display panel; and
a plurality of dummy insulating patterns arranged to be adjacent to two opposite sides of at least one conductive pattern among the plurality of conductive patterns, and
wherein:
the at least one conductive pattern comprises a first conductive layer, a second conductive layer, and a third conductive layer sequentially stacked in the thickness direction; and
the plurality of dummy insulating patterns are arranged between the first conductive layer and the third conductive layer and cover two opposite sides of the second conductive layer.

2. The electronic device of claim 1, wherein the plurality of dummy insulating patterns comprise an inorganic material.

3. The electronic device of claim 2, wherein both ends of the second conductive layer are arranged further inward than both ends of the first conductive layer and both ends of the third conductive layer.

4. The electronic device of claim 1, wherein the input sensing unit comprises:
a base layer in contact with the display panel;
a first sensing conductive layer on the base layer;
a first sensing insulating layer on the first sensing conductive layer;
a second sensing conductive layer on the first sensing insulating layer; and
a second sensing insulating layer on the second sensing conductive layer and comprising an organic material, and
wherein the second sensing conductive layer comprises a same material as any one of the conductive patterns.

5. The electronic device of claim 4, wherein the second sensing insulating layer does not overlap the bending portion and the pads.

6. The electronic device of claim 5, wherein:
the display panel further comprises a data driver between the pads and the bending portion in plan view; and
the second sensing insulating layer does not overlap the data driver.

7. The electronic device of claim 4, wherein a thickness of the second sensing insulating layer is 3.4 to 3.8 times greater than a thickness of the second sensing conductive layer.

8. The electronic device of claim 4, wherein:
the first non-bending portion comprises a first non-folding region, a folding region, and a second non-folding region arranged in the first direction; and
the second sensing insulating layer overlaps the folding region.

9. The electronic device of claim 1, wherein the second conductive layer comprises a material different from those of the first conductive layer and the third conductive layer.

10. An electronic device, comprising:
a display panel comprising a first non-bending portion, a bending portion, and a second non-bending portion arranged in a first direction, the display panel further comprising a plurality of pads arranged in the second non-bending portion; and
an input sensing unit on the display panel,
wherein the input sensing unit comprises:
a base layer in contact with the display panel;
a first sensing conductive layer on the base layer;
a first sensing insulating layer on the first sensing conductive layer;
a second sensing conductive layer on the first sensing insulating layer; and
a second sensing insulating layer on the second sensing conductive layer and comprising an organic material, and
wherein the second sensing insulating layer does not overlap the bending portion and the pads.

11. The electronic device of claim 10, wherein:
the display panel further comprises a data driver between the pads and the bending portion in plan view; and
the second sensing insulating layer does not overlap the data driver.

12. The electronic device of claim 10, wherein a thickness of the second sensing insulating layer is 3.4 to 3.8 times greater than a thickness of the second sensing conductive layer.

13. The electronic device of claim 10, wherein:
the first non-bending portion comprises a first non-folding region, a second non-folding region, and a folding region, which are arranged in the first direction, with the folding region being between the first non-folding region and the second non-folding region and folded around a folding axis parallel to a second direction crossing the first direction; and
the second sensing insulating layer overlaps the folding region.

14. The electronic device of claim 11, wherein the plurality of pads comprise:
a plurality of conductive patterns stacked in a thickness direction of the display panel; and
a plurality of dummy insulating patterns arranged adjacent to two opposite sides of at least one conductive pattern among the plurality of conductive patterns.

15. The electronic device of claim 14, wherein:
the at least one conductive pattern comprises a first conductive layer, a second conductive layer, and a third conductive layer which are stacked in a bottom-to-top order; and
the plurality of dummy insulating patterns are arranged between the first conductive layer and the third conductive layer and cover two opposite sides of the second conductive layer.

16. The electronic device of claim 15, wherein the plurality of dummy insulating patterns comprise an inorganic material.

17. The electronic device of claim 15, wherein both ends of the second conductive layer are arranged further inward than both ends of the first conductive layer and both ends of the third conductive layer.

18. The electronic device of claim 15, wherein the second conductive layer comprises a material different from those of the first conductive layer and the third conductive layer.

19. The electronic device of claim 1, wherein the electronic device does not comprise a polarizing film inside the display panel, between the display panel and the input sensing unit, between the input sensing unit and the anti-reflection layer, or on the anti-reflection layer.

20. A method, comprising:
preparing a display panel, which is divided into a first non-bending portion, a bending portion, and a second non-bending portion arranged in a first direction and comprises a plurality of pads arranged in the second non-bending portion, and a first sensing conductive layer, a first sensing insulating layer, and a second sensing conductive layer which are sequentially stacked in the first non-bending portion;
providing an organic material on the second non-bending portion and the second sensing conductive layer to form a preliminary sensing insulating layer;
etching the preliminary sensing insulating layer overlapping the pads and the bending portion to form a second sensing insulating layer;
providing an inorganic material on the second sensing insulating layer, the pads, and the bending portion to form a preliminary insulating layer; and
etching the preliminary insulating layer on the first non-bending portion, the bending portion, and the second non-bending portion to form a plurality of dummy insulating patterns adjacent to two opposite sides of the pads,
wherein the plurality of pads comprise a plurality of conductive patterns stacked in a thickness direction of the display panel,
wherein:
at least one conductive pattern among the plurality of conductive patterns comprises a first conductive layer, a second conductive layer, and a third conductive layer stacked in a bottom-to-top order; and
the plurality of dummy insulating patterns are formed between the first conductive layer and the third conductive layer and cover two opposite sides of the second conductive layer, and
wherein the method is a method for manufacturing an electronic device.
